(19) United States
(12) Patent Application Publication
(10) Pub. No.: US 2025/0151567 A1
(43) Pub. Date: May 8, 2025

(54) LIGHT CONTROL MEMBER, DISPLAY DEVICE INCLUDING THE SAME, AND MANUFACTURING METHOD OF THE DISPLAY DEVICE

(71) Applicant: Samsung Display Co., Ltd., Yongin-si (KR)

(72) Inventors: JUO NAM, Yongin-si (KR); KAWON PAK, Yongin-si (KR); SEUNG-WON PARK, Yongin-si (KR); KYUNGSIG LEE, Yongin-si (KR); TAEKJOON LEE, Yongin-si (KR); SEUNGHEE JANG, Yongin-si (KR); JAEBOK CHANG, Yongin-si (KR)

(21) Appl. No.: 18/930,664

(22) Filed: Oct. 29, 2024

(30) Foreign Application Priority Data
Nov. 2, 2023 (KR) 10-2023-0150039

(51) Int. Cl. H10K 59/38; B82Y 20/00; B82Y 40/00; G03F 7/004; G03F 7/075

(52) U.S. Cl. CPC H10K 59/38; G03F 7/0047; G03F 7/0755; B82Y 20/00; B82Y 40/00

(57) ABSTRACT

A light control member includes: a base layer; a partition wall part on the base layer, where multiple opening parts are defined in the partition wall part; multiple light control patterns in the multiple opening parts; and a surface modification layer between the base layer and the multiple light control patterns and including a first chemical moiety represented by Formula 1.

*—(R¹)₂Si—L₁—R²—L₂—R³ Formula 1

### CROSS-REFERENCE TO RELATED APPLICATION

The present application claims priority to and the benefit of Korean Patent Application No. 10-2023-0150039, filed on Nov. 2, 2023, in the Korean Intellectual Property Office, the entire content of which is incorporated herein by reference.

### BACKGROUND

### 1. Field

One or more embodiments of the present disclosure relate to a light control member, a display device including the light control member, and a manufacturing method of the display device.

### 2. Description of Related Art

A display device may be categorized as a transmission type or kind display panel selectively transmitting source light produced from a light source or an emission type or kind display panel producing source light in the display panel itself. The display panel may include different types (kinds) of light control patterns according to pixels for producing color images. The light control pattern may be to transmit partial wavelength range of the source light or convert the color of the source light. A portion of the light control pattern may also change the optical properties without changing the color of the source light.

### SUMMARY

One or more aspects of embodiments of the present disclosure are directed toward a light control member and a display device having improved durability and reliability. Additional aspects will be set forth in part in the description which follows and, in part, will be apparent from the description, or may be learned by practice of the presented embodiments.

According to one or more embodiments of the present disclosure, a light control member includes a base layer, a partition wall part on (e.g., arranged on) the base layer, where multiple opening parts are defined in the partition wall part, multiple light control patterns in (e.g., correspondingly arranged in) the multiple opening parts, and a surface modification layer arranged between the base layer and the multiple light control patterns and includes a first compound (e.g., a first chemical moiety) represented by Formula 1.

*—(R¹)₂Si—L₁—R²—L₂—R³ Formula 1

In Formula 1, R¹ may be a hydroxyl group, a substituted or unsubstituted alkoxy group of 1 to 20 carbon atoms, or a substituted or unsubstituted alkyl group of 1 to 20 carbon atoms, L₁ and L₂ may each independently be a direct linkage, —O—, —S—, —NHR⁴—, —O—C(═O)—, —O—C(═S)—, —O—C(═O)R⁴—, —O—C(═S)R⁴—, —C(═O)—, —C(═S)—, —C(═O)R⁴—, —C(═S)R⁴—, —C(═O) NH—, —OC(═O) NH—, —C(═O) NHR⁴—, —OC(═O) NHR⁴—, or a substituted or unsubstituted alkylene group of 1 to 20 carbon atoms, R² may be —(O(C₂H₄))ₘ—, R³ may be a substituted or unsubstituted(meth)acrylate group, a substituted or unsubstituted alkyl group of 1 to 20 carbon atoms, or a substituted or unsubstituted aryl group of 6 to 30 ring-forming carbon atoms, R⁴ may be a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, “m” is an integer of 0 to 30, and “*------” is a position connected with the base layer.

In one or more embodiments, in Formula 1, R³ may be a substituted or unsubstituted alkyl group of 1 to 10 carbon atoms.

In one or more embodiments, the first compound (e.g., the first chemical moiety) represented by Formula 1 may be represented by Formula 2.

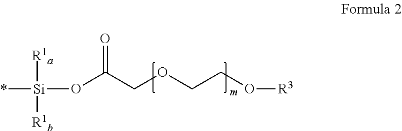

In Formula 2, R¹ₐ and R¹_{b} may each independently be a hydroxyl group, a substituted or unsubstituted alkoxy group of 1 to 20 carbon atoms, or a substituted or unsubstituted alkyl group of 1 to 20 carbon atoms.

In Formula 2, the same explanation defined in Formula 1 may be applied for R³ and “m”.

In one or more embodiments, the surface modification layer may be arranged on a side (e.g., one side) of the base layer exposed by the multiple opening parts.

In one or more embodiments, the surface modification layer may be arranged in the multiple opening parts.

In one or more embodiments, the partition wall part may include a first side adjacent to the base layer, a second side oppositely arranged to the first side, and a third side connecting the first side and the second side, and at least a portion of the surface modification layer may be arranged on the third side and the second side of the partition wall part.

In one or more embodiments, the light control member may further include a reflection pattern arranged on the third side of the partition wall part, and the surface modification layer may be arranged between the reflection pattern and the light control patterns.

In one or more embodiments, at least one selected from among the multiple light control patterns may include a quantum dot.

In one or more embodiments, the quantum dot may include a core, a shell wrapping the core, and a ligand bonded to a surface of the shell and including a hydrophilic group.

In one or more embodiments, the multiple light control patterns may include a first light control pattern including a first quantum dot converting source light into first light, a second light control pattern including a second quantum dot converting the source light into second light, and a third light control pattern transmitting the source light.

In one or more embodiments, a weight of the first quantum dot may be about 50 wt % to about 70 wt % on the basis of a total weight of the first light control pattern, and a weight of the second quantum dot may be about 50 wt % to about 70 wt % on the basis of a total weight of the second light control pattern.

According to one or more embodiments of the present disclosure, a display device includes a light emitting element including a first electrode, an emission layer on (e.g., arranged on) the first electrode, and a second electrode on (e.g., arranged on) the emission layer, and configured to emit source light, and a light control member on (e.g., arranged on) the light emitting element, wherein the light control member includes a base layer on (e.g., arranged on) the light emitting element, a light control layer on (e.g., arranged on) the light emitting element and including at least one light control pattern, and a surface modification layer arranged between the base layer and the at least one light control pattern and including a first compound (e.g., a first chemical moiety) represented by Formula 1.

*—(R¹)₂Si—L₁—R²—L₂—R³ Formula 1

In Formula 1, R¹ may be a hydroxyl group, a substituted or unsubstituted alkoxy group of 1 to 20 carbon atoms, or a substituted or unsubstituted alkyl group of 1 to 20 carbon atoms, L₁ and L₂ may each independently be a direct linkage, —O—, —S—, —NHR⁴—, —O—C(═O)—, —O—C(═S)—, —O—C(═O)R⁴—, —O—C(═S)R⁴—, —C(═O)—, —C(═S)—, —C(═O)R⁴—, —C(═S)R⁴—, —C(═O) NH—, —OC(═O) NH—, —C(═O) NHR⁴—, —OC(═O) NHR⁴—, or a substituted or unsubstituted alkylene group of 1 to 20 carbon atoms, R² may be —(O(C₂H₄))ₘ—, R³ may be a substituted or unsubstituted(meth)acrylate group, a substituted or unsubstituted alkyl group of 1 to 20 carbon atoms, or a substituted or unsubstituted aryl group of 6 to 30 ring-forming carbon atoms, R⁴ may be a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, “m” is an integer of 0 to 30, and “*” is a position connected with the base layer.

In one or more embodiments, the at least one light control pattern may include a first light control pattern including a first quantum dot converting the source light into first light, a second light control pattern including a second quantum dot converting the source light into second light, and a third light control pattern transmitting the source light.

In one or more embodiments, the light control member may further include a color filter layer on (e.g., arranged on) the light control layer, and the color filter layer may include a first color filter transmitting the first light, a second color filter transmitting the second light, and a third color filter transmitting the source light.

In one or more embodiments, the base layer may include at least one selected from among silicon oxide, silicon nitride, and silicon oxynitride.

In one or more embodiments, the light control pattern may include one side adjacent to the base layer, and the other side oppositely arranged to the one side and separated from the base layer, and the surface modification layer may make contact with the one side of the light control pattern.

In one or more embodiments, the display device may further include a filling layer arranged between the light emitting element and the light control member and covering the light emitting element.

According to one or more embodiments of the present disclosure, a method of manufacturing a display device includes preparing a display panel, and forming (or providing) a light control member on the display panel, wherein the forming (or providing) of the control member includes preparing a base layer, forming (or providing) a surface modification layer including a first compound (e.g., a first chemical moiety) represented by Formula 1 on the base layer, providing a photoresist composition including a quantum dot on the surface modification layer to form (or provide) a preliminary light control pattern, and exposing and developing the preliminary light control pattern to form (or provide) a light control pattern.

*—(R¹)₂Si—L₁—R₂—L₂—R₃ Formula 1

In Formula 1, R¹ may be a hydroxyl group, a substituted or unsubstituted alkoxy group of 1 to 20 carbon atoms, or a substituted or unsubstituted alkyl group of 1 to 20 carbon atoms, L₁ and L₂ may each independently be a direct linkage, —O—, —S—, —NHR⁴—, —O—C(═O)—, —O—C(═S)—, —O—C(═O)R⁴—, —O—C(═S)R⁴—, —C(═O)—, —C(═S)—, —C(═O)R⁴—, —C(═S)R⁴—, —C(═O) NH—, —OC(═O) NH—, —C(═O) NHR⁴—, —OC(═O) NHR⁴—, or a substituted or unsubstituted alkylene group of 1 to 20 carbon atoms, R² may be —(O(C₂H₄))ₘ—, R³ may be a substituted or unsubstituted(meth)acrylate group, a substituted or unsubstituted alkyl group of 1 to 20 carbon atoms, or a substituted or unsubstituted aryl group of 6 to 30 ring-forming carbon atoms, R⁴ may be a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, “m” is an integer of 0 to 30, and “*” is a position connected with the base layer.

In one or more embodiments, the forming (or providing) of the light control member may further include forming (or providing) a partition wall part on the base layer, where multiple opening parts are defined in the partition wall part, prior to forming (or providing) the surface modification layer, and the photoresist composition may be provided in the multiple opening parts.

In one or more embodiments, the method may further include treating a surface of the base layer with ozone and/or ultraviolet to form (or provide) a hydroxyl group on the surface of the base layer, prior to forming (or providing) the surface modification layer.

### BRIEF DESCRIPTION OF DRAWINGS

The accompanying drawings are included to provide a further understanding of the present disclosure and are incorporated in and constitute a part of this disclosure. The drawings illustrate embodiments of the present disclosure and, together with the description, serve to explain principles of the present disclosure. Above and/or other aspects of the present disclosure should become apparent and appreciated from the following description of embodiments taken in conjunction with the accompanying drawings. In the drawings:

FIG. 1A is a perspective view of a display device according to one or more embodiments of the present disclosure;

FIG. 1B is a cross-sectional view of a display device according to one or more embodiments of the present disclosure;

FIG. 1C is a plan view of a display panel according to one or more embodiments of the present disclosure;

FIG. 2 is an enlarged plan view of a portion of a display panel according to one or more embodiments of the present disclosure;

FIG. 3 is a cross-sectional view of a display device according to one or more embodiments of the present disclosure;

FIG. 4A and FIG. 4B each show an enlarged view of a partial region in the cross-section of a display device according to one or more embodiments of the present disclosure;

FIG. 5A and FIG. 5B each show an enlarged view of a partial region in the cross-sections of a display device according to one or more embodiments of the present disclosure;

FIG. 6 is a flowchart showing a method of manufacturing a display device according to one or more embodiments of the present disclosure;

FIG. 7A-FIG. 7J are each a diagram showing the steps of a method of manufacturing a display device according to one or more embodiments of the present disclosure;

FIG. 8A and FIG. 8B are each a photographic image of a light control pattern of one or more embodiments, observed by an electron microscope; and

FIG. 9A, FIG. 9B, FIG. 9C, FIG. 10A, and FIG. 10B are each a photographic image of a light control pattern of a comparative embodiment, observed by an electron microscope.

### DETAILED DESCRIPTION

Hereinafter, example embodiments of the present disclosure will be explained referring to the drawings.

In the description, if (e.g., when) an element (or a region, a layer, a part, and/or the like) is referred to as being “on”, “connected with,” or “combined with” another element, it may be directly arranged on/connected with/bonded to the other element, or intervening third elements may also be arranged.

Like reference numerals refer to like elements throughout the present disclosure, and duplicative descriptions thereof may not be provided for conciseness.

In the drawings, the thicknesses, ratios, and dimensions of elements may be exaggerated for effective explanation of technical contents. The term “and/or” or “or” may include one or more combinations that may define relevant elements. Expressions such as “at least one of,” “one of,” and “selected from,” when preceding a list of elements, modify the entire list of elements and do not modify the individual elements of the list. For example, “at least one of a, b, or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

It will be understood that, although the terms first, second, and/or the like may be utilized herein to describe one or more suitable elements, these elements should not be limited by these terms. These terms are only utilized to distinguish one element from another element. For example, a first element could be termed a second element without departing from the scope of the present disclosure. Similarly, a second element could be termed a first element. As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure.”

In one or more embodiments, the terms “below,” “beneath,” “on” and “above” are utilized for explaining the relation of elements shown in the drawings. The terms are relative concept and are explained based on the direction shown in the drawing.

It will be further understood that the terms “comprise(s)/comprising,” “include(s)/including,” or “have/has/having,” when utilized in the present disclosure, specify the presence of stated features, numerals, steps, operations, elements, parts, or a combination thereof, but do not preclude the presence or addition of one or more other features, numerals, steps, operations, elements, parts, or a combination thereof.

In the disclosure, “directly arranged” may refer to that there is no additional layer, film, area, and/or plate between a part such as a layer, film, area and another part. For example, “directly arranged” may refer to that two layers or two members are arranged without utilizing an additional member such as an adhesive member therebetween.

Unless otherwise defined, all terms (including technical and scientific terms) utilized herein have the same meaning as commonly understood by one of ordinary skill in the art to which this present disclosure belongs. In one or more embodiments, it will be further understood that terms, such as those defined in commonly utilized dictionaries, should be interpreted as having a meaning that is consistent with their meaning in the context of the relevant art and will not be interpreted in an idealized or overly formal sense unless expressly defined so herein.

Hereinafter, a light control member according to one or more embodiments of the present disclosure and a display device including the light control member will be explained referring to the drawings.

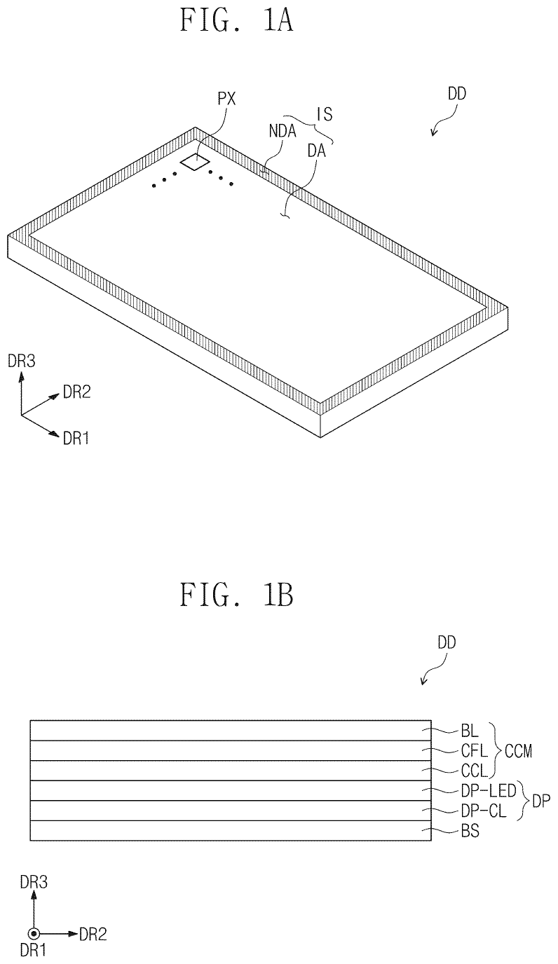

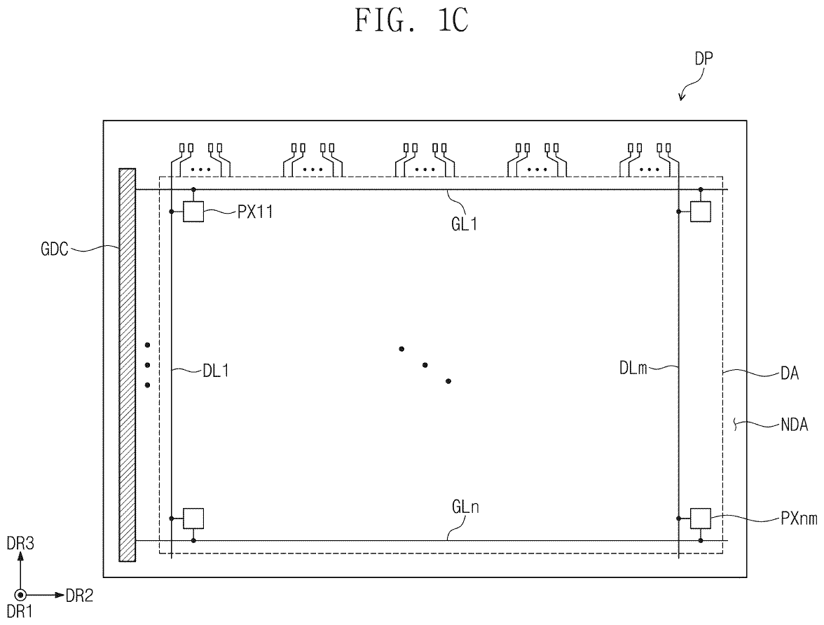

FIG. 1A is a perspective view of a display device according to one or more embodiments of the present disclosure. FIG. 1B is a cross-sectional view of a display device according to one or more embodiments of the present disclosure. FIG. 1C is a plan view of a display panel according to one or more embodiments of the present disclosure.

As shown in FIG. 1A, a display device DD may display images through a display surface IS. The display surface IS is parallel to a surface defined by a first direction DR1 and a second direction DR2. The display surface IS may include a display area DA and a non-display area NDA. In the display area DA, a pixel PX is arranged and provided, and in the non-display area NDA, the pixel PX is not arranged. The non-display area NDA is defined along the border of the display surface IS. The non-display area NDA may surround the display area DA. However, embodiments of the present disclosure are not limited thereto, and in some embodiments of the present disclosure, the non-display area NDA may not be provided or, in some embodiments, may be arranged only at one side of the display area DA.

The normal line direction of the display surface IS, i.e., the thickness direction of the display device DD is indicated by a third direction DR3. The front surface (or top) and the rear surface (or bottom) of layers and units may be divided based on the third direction DR3. However, the first to third directions DR1, DR2 and DR3, shown in these embodiments are only mere examples.

In one or more embodiments of the present disclosure, the display device DD provided with a planar display surface IS is shown, but embodiments of the present disclosure are not limited thereto. In one or more embodiments, the display device DD may include a curve-type or kind display surface or a three-dimensional display surface. The three-dimensional display surface may include multiple display areas indicating other directions from each other.

As shown in FIG. 1B, the display device DD may include a display panel DP and a light control member CCM on (e.g., arranged on) the display panel DP.

The display panel DP may include a first base substrate BS, a circuit element layer DP-CL on (e.g., arranged on) the first base substrate BS, and a display element layer DP-LED. The first base substrate BS may include a synthetic resin substrate or a glass substrate. The circuit element layer DP-CL may include at least one insulating layer and a circuit element. The circuit element may include a signal line, the driving circuit of a pixel, and/or the like. The circuit element layer DP-CL may be formed through a forming (or providing) process of an insulating layer, a semiconductor layer, and a conductive layer by coating, deposition, and/or the like, and a patterning process of the insulating layer, the semiconductor layer, and the conductive layer by a photolithography process. The display element layer DP-LED may include at least a display element.

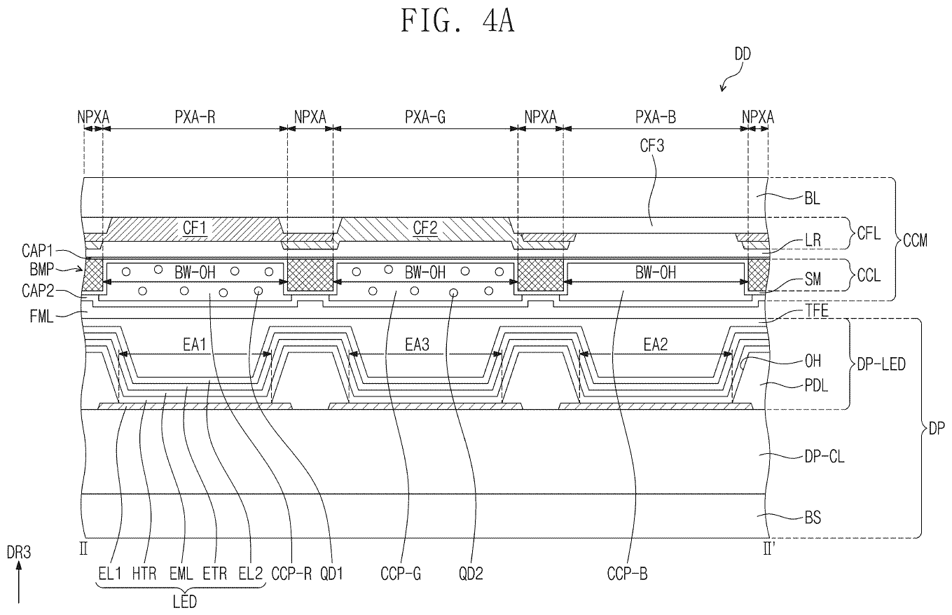

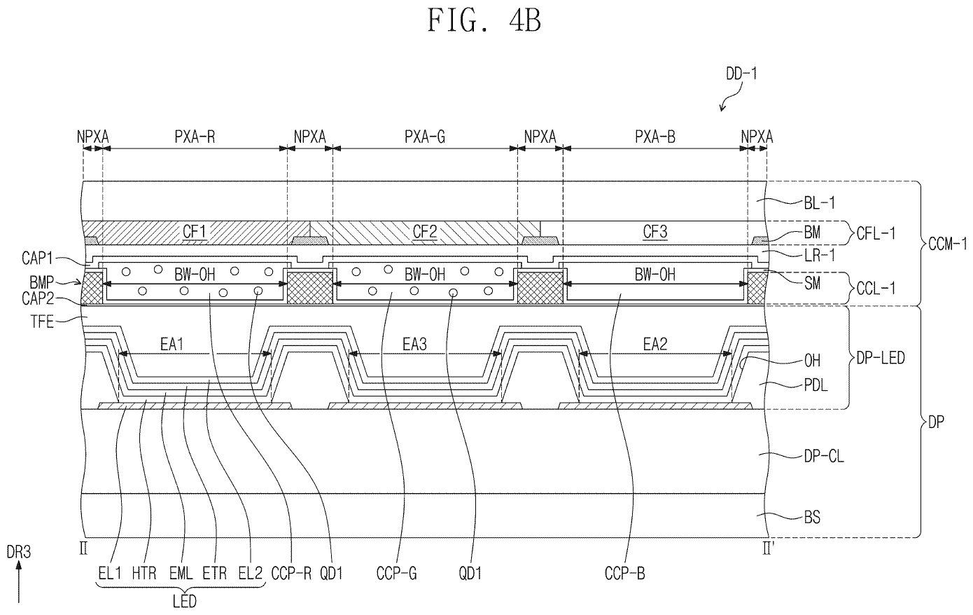

The light control member CCM is provided on the display panel DP. The light control member CCM may convert the color of light provided from the display element. The light control member CCM may include a light control pattern and a structure for increasing the conversion efficiency of light. The light control member CCM may include a light control layer CCL, a color filter layer CFL, and a second base substrate BL. For example, in one or more embodiments, the display panel DP may include a light emitting element LED (see FIG. 4A and FIG. 4B) configured to emit first light, and the light control member CCM may include light control patterns CCP-R, CCP-G, and CCP-B (see FIG. 4A and FIG. 4B) configured to convert the wavelength of the first light provided from the light emitting element LED (see FIG. 4A and FIG. 4B) or transmitting the first light.

FIG. 1C shows the relation of a planar arrangement of signal lines GL1 to GLn and DL1 to DLm, and pixels PX11 to PXnm. Referring to FIG. 1C, in one or more embodiments, the display panel DP may include the signal lines GL1 to GLn and DL1 to DLm, and the pixels PX11 to PXnm. The signal lines GL1 to GLn and DL1 to DLm may include multiple gate lines GL1 to GLn and multiple data lines DL1 to DLm.

Each of the pixels PX11 to PXnm is connected with a corresponding gate line among the multiple gate lines GL1 to GLn and a corresponding data line among the multiple data lines DL1 to DLm. Each of the pixels PX11 to PXnm may include a pixel driving circuit and a display element. According to the configuration of the pixel driving circuits of the pixels PX11 to PXnm, more types (kinds) of signal lines may be provided in the display panel DP.

The pixels PX11 to PXnm having a matrix type or kind is shown as an example, but embodiments of the present disclosure are not limited thereto. The pixels PX11 to PXnm may be arranged in a pentile (Pentile®) type or kind. For example, in one or more embodiments, the points where the pixels PX11 to PXnm are arranged may correspond to the apexes of diamonds. A gate driving circuit GDC may be integrated on the display panel DP through an oxide silicon gate driver circuit (OSG) or amorphous silicon gate driver circuit (ASG) process. Pentile® is a duly registered trademark of Samsung Display Co., Ltd.

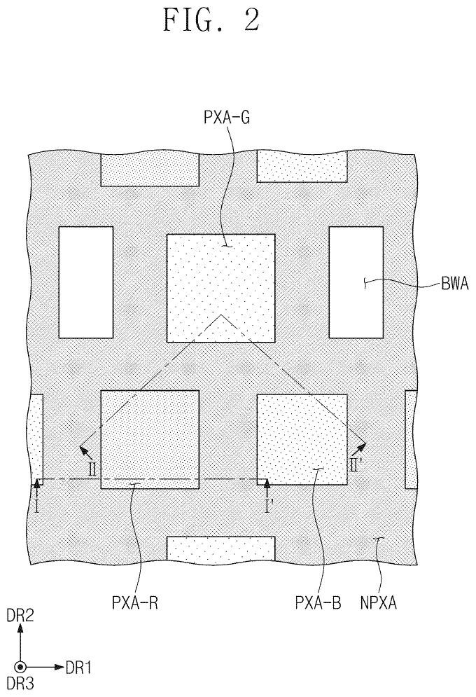

FIG. 2 is an enlarged plan view of a portion of a display panel according to one or more embodiments of the present disclosure. In FIG. 2, in the display device DD (see FIG. 1A) of one or more embodiments, a plane including three pixel areas PXA-R, PXA-B, and PXA-G, and an adjacent bank well area BWA is shown as an example. In one or more embodiments of the present disclosure, the three types (kinds) of the pixel areas PXA-R, PXA-B and PXA-G may be repeatedly arranged over the entire display area DA (see FIG. 1A).

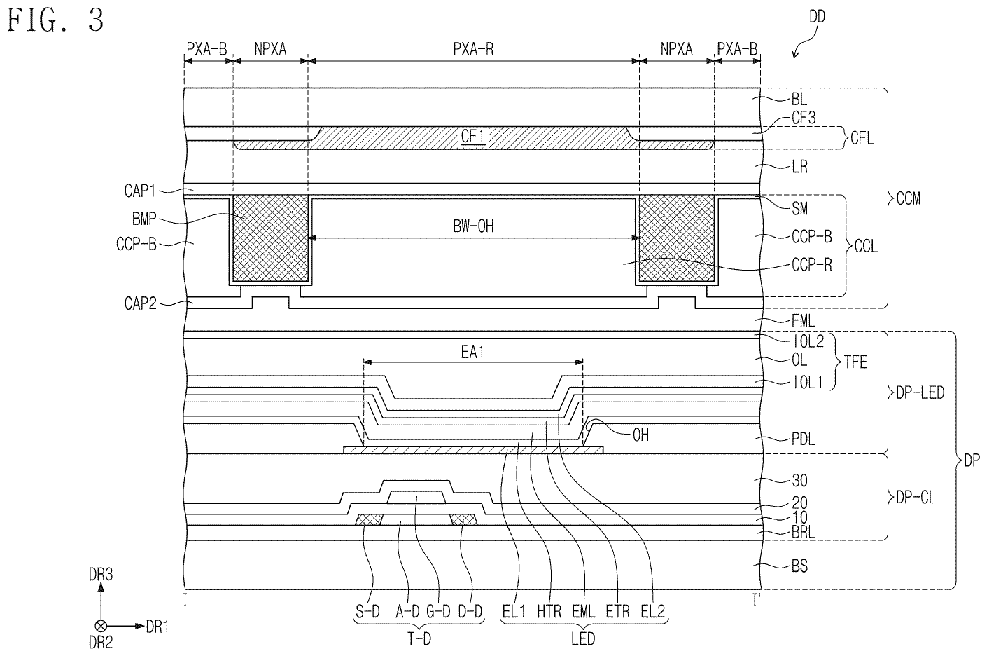

Around the first to third pixel areas PXA-R, PXA-B, and PXA-G, a peripheral area NPXA is arranged. The peripheral area NPXA defines the boundary of the first to third pixel areas PXA-R, PXA-B, and PXA-G. The peripheral area NPXA may surround the first to third pixel areas PXA-R, PXA-B and PXA-G. In the peripheral area NPXA, a structure preventing or reducing the mixing of colors among the first to third pixel areas PXA-R, PXA-B and PXA-G, for example, a pixel definition layer PDL (see FIG. 3) or a partition wall part BMP (see FIG. 3), may be arranged.

In FIG. 2, the first to third pixel areas PXA-R, PXA-B, and PXA-G having the same plane shape and substantially the same plane area are shown as examples, but embodiments of the present disclosure are not limited thereto. The areas of at least two or more selected from among the first to third pixel areas PXA-R, PXA-B and PXA-G may be substantially the same. The areas of the first to third pixel areas PXA-R, PXA-B and PXA-G may be determined according to the color of emitting light. In one or more embodiments, the area of a pixel area emitting green light among primary colors may be the largest, and the area of a pixel area emitting blue light may be the smallest.

In FIG. 2, the first to third pixel areas PXA-R, PXA-B, and PXA-G having a square shape are shown, but embodiments of the present disclosure are not limited thereto. In one or more embodiments, on a plane (e.g., in a plan view), the first to third pixel areas PXA-R, PXA-B, and PXA-G may have a polygonal shape of another shape (substantially a polygonal shape) such as a trapezoid or a pentagon. In some embodiments, the first to third pixel areas PXA-R, PXA-B, and PXA-G may have a square shape having round corners (substantially a square).

In FIG. 2, a second pixel area PXA-G is arranged in a first row, and a first pixel area PXA-R and a third pixel area PXA-B are arranged in a second row as an example, but embodiments of the present disclosure are not limited thereto. The arrangement of the first to third pixel areas PXA-R, PXA-B, and PXA-G may be changed diversely and suitably. For example, in some embodiments, the first to third pixel areas PXA-R, PXA-B and PXA-G may be arranged in substantially the same row.

In one or more embodiments, one selected from among the first to third pixel areas PXA-R, PXA-B, and PXA-G provides third light corresponding to source light, another one provides first light which is different from the third light, and the remaining one provides second light which is different from the first light and the third light. In these embodiments, the third pixel area PXA-B provides the third light which corresponds to the source light. For example, the first pixel area PXA-R may provide red light, the second pixel area PXA-G may provide green light, and the third pixel area PXA-B may provide blue light.

In the display area DA (see FIG. 1A), a bank well area BWA may be defined. The bank well area BWA may be an area formed for preventing or reducing defects due to mis-landing during the patterning process of multiple light control patterns CCP-R, CCP-B, and CCP-G (see FIG. 4A) included in the light control layer CCL (see FIG. 4A). For example, in one or more embodiments, the bank well area BWA may be an area formed by removing a portion of the partition wall part BMP (see FIG. 4A). In FIG. 2, two bank well areas BWA adjacent to the second pixel area PXA-G are defined as an example. But embodiments of the present disclosure are not limited thereto, and the shape and arrangement of the bank well areas BWA may be changed diversely and suitably.

FIG. 3 is a cross-sectional view of a display device according to one or more embodiments of the present disclosure. FIG. 4A shows an enlarged view of a partial region in the cross-section of a display device according to one or more embodiments of the present disclosure. FIG. 3 is a cross-sectional view of a light emitting element included in the display device according to one or more embodiments of the present disclosure. FIG. 4A shows the cross-section corresponding to a cutting-line II-II′ in FIG. 2.

Referring to FIG. 3, the display device DD of one or more embodiments may include a first base substrate BS, a circuit element layer DP-CL on (e.g., arranged on) the base substrate BS and a display element layer DP-LED on (e.g., arranged on) the circuit element layer DP-CL. In the description, the first base substrate BS, the circuit element layer DP-CL, and the display element layer DP-LED altogether may be referred to as a lower panel.

The first base substrate BS may be a member providing a base surface for arranging a configuration including the circuit element layer DP-CL. In one or more embodiments, the first base substrate BS may be a glass substrate, a metal substrate, a polymer substrate, and/or the like. However, embodiments of the present disclosure are not limited thereto, and the first base substrate BS may be an inorganic layer, a functional layer, or a composite material layer.

The first base substrate BS may have a multilayer structure. For example, in some embodiments, the first base substrate BS may have a three-layer structure of a polymer resin layer, an adhesive layer, and a polymer resin layer. For example, the polymer resin layer may include a polyimide-based resin. In one or more embodiments, the polymer resin layer may include at least one selected from among an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. In the present disclosure, “component-based” resin refers to a resin including the functional group of “component.”

The circuit element layer DP-CL may be arranged on the first base substrate BS. The circuit element layer DP-CL may include a transistor T-D as a circuit element. According to the design of the driving circuit of a pixel PX (see FIG. 1A), the configuration of the circuit element layer DP-CL may be changed, and one transistor T-D is shown as an example in FIG. 3. The relation of the arrangement of an active A-D, a source S-D, a drain D-D, and a gate G-D, constituting the transistor T-D is shown as an example. The active A-D, the source S-D, and the drain D-D may be areas divided according to the doping concentration or conductivity of a semiconductor pattern. The circuit element layer DP-CL may include a lower buffer layer BRL

arranged on the first base substrate BS, a first insulating layer 10, a second insulating layer 20, and a third insulating layer 30. For example, in some embodiments, the lower buffer layer BRL, the first insulating layer 10, and the second insulating layer 20 may be inorganic layers, and the third insulating layer 30 may be an organic layer.

The display element layer DP-LED may include a light emitting element LED as a display element. The light emitting element LED may produce the above-described source light. The light emitting element LED includes a first electrode EL1, a second electrode EL2, and an emission layer EML arranged therebetween. In one or more embodiments, the display element layer DP-LED may include an organic light emitting diode as the light emitting element. In one or more embodiments of the present disclosure, the light emitting element may include a quantum dot light emitting diode. For example, the emission layer EML included in the light emitting element LED may include an organic light emitting material as a light emitting material, or the emission layer EML may include a quantum dot as the light emitting material. In one or more embodiments, the display element layer DP-LED may include a subminiature light emitting element as the light emitting element. The subminiature light emitting element may include, for example, a micro LED element and/or a nano LED element. The subminiature light emitting element may have a micro- or nano-scale size, and may be a light emitting element including an active layer arranged among multiple semiconductor layers.

The first electrode EL1 is on (e.g., arranged on) the third insulating layer 30. The first electrode EL1 may be directly or indirectly connected with the transistor T-D, and the connected structure of the first electrode EL1 and the transistor T-D is not shown in FIG. 3.

In one or more embodiments, the display element layer DP-LED may include a pixel definition layer PDL. For example, in some embodiments, the pixel definition layer PDL may be an organic layer. In the pixel definition layer PDL, a light emitting opening part OH is defined. The light emitting opening part OH of the pixel definition layer PDL may expose at least a portion of the first electrode EL1. In these embodiments, a first light emitting area EA1 may be defined by the light emitting opening part OH.

In one or more embodiments, a hole control layer HTR, the emission layer EML, and an electron control layer ETR overlap with at least the pixel area PXA-R. The hole control layer HTR, the emission layer EML, the electron control layer ETR, and the second electrode EL2 may be provided in the first to third pixel areas PXA-R, PXA-G, and PXA-B (see FIG. 4A) as common layers. Each of the hole control layer HTR, the emission layer EML, the electron control layer ETR, and the second electrode EL2 overlapping with the first to third pixel areas PXA-R, PXA-G, and PXA-B (FIG. 4A) may have a shape of one body. However, embodiments of the present disclosure are not limited thereto, for example, in some embodiments, at least one selected from among the hole control layer HTR, the emission layer EML, the electron control layer ETR, and the second electrode EL2 may be separately formed in each of the first to third pixel areas PXA-R, PXA-G, and PXA-B (see FIG. 4A). In one or more embodiments, the emission layer EML may be patterned in the light emitting opening part OH and separately formed in each of the first to third pixel areas PXA-R, PXA-G, and PXA-B (see FIG. 4A).

The hole control layer HTR may include a hole transport layer and may further include a hole injection layer.

The emission layer EML may produce third light which is the source light. In one or more embodiments, the emission layer EML may produce blue light. The blue light may include the light of a wavelength of about 410 nanometer (nm) to about 480 nm. The emission spectrum of the blue light may have a maximum peak in a wavelength range of about 440 nm to about 460 nm.

The electron control layer ETR may include an electron transport layer and may further include an electron injection layer.

The display element layer DP-LED may include a thin film encapsulating layer TFE protecting the second electrode EL2. The thin film encapsulating layer TFE may include an organic material and/or an inorganic material. In one or more embodiments, the thin film encapsulating layer TFE may have a multilayer structure in which an inorganic layer and an organic layer are repeated. In these embodiments, the thin film encapsulating layer TFE may include first encapsulating inorganic layer IOL1/encapsulating organic layer OL/second encapsulating inorganic layer IOL2. The first and second encapsulating inorganic layers IOL1 and IOL2 may protect the light emitting element LED from external moisture, and the encapsulating organic layer OL may prevent or reduce the impressing defects of the light emitting element LED by foreign materials introduced during a manufacturing process. In one or more embodiments, the display panel DP may further include a refractive index control layer for improving light emitting efficiency on the thin film encapsulating layer TFE.

Referring to FIG. 3 and FIG. 4A, in one or more embodiments, a light control member CCM may be arranged on the thin film encapsulating layer TFE. The light control member CCM may include a light control layer CCL, a low refractive layer LR, a color filter layer CFL, and a second base substrate BL. In the description, the light control member CCM may be referred to as an upper panel.

The light control layer CCL may be arranged on the display element layer DP-LED including the light emitting element LED. The light control layer CCL may include a partition wall part BMP, a surface modification layer SM, and light control patterns CCP-R, CCP-G, and CCP-B.

The partition wall part BMP may include a base resin and an additive. The base resin may be composed of one or more suitable resin compositions which may generally be referred to as binders. The additive may include a coupling agent and/or a photoinitiator. The additive may further include a dispersant.

The partition wall part BMP may include a black coloring agent for blocking light. The partition wall part BMP may include a black dye and/or a black pigment mixed with a base resin. In some embodiments, the black coloring agent may include carbon black or a metal like chromium, or the oxides thereof.

In the partition wall part BMP, a partition wall opening part BW-OH corresponding to the light emitting opening part OH may be defined. On a plane (e.g., in a plan view), the partition wall opening part BW-OH overlaps with the light emitting opening part OH and may have an area greater than that of the light emitting opening part OH. For example, in one or more embodiments, the partition wall opening part BW-OH may have an area greater than an area of the light emitting area EA1 defined by the light emitting opening part OH. In the disclosure, “corresponding” refers to overlapping of two configurations when viewed in the thickness direction DR3 (in a plan view) of a display panel DP, and the areas of the two configurations are not limited to be the same.

In one or more embodiments, the light control member CCM may include a base layer providing a base surface for forming (or providing) the light control patterns CCP-R, CCP-G, and CCP-B. The base layer may be arranged adjacent to the light control patterns CCP-R, CCP-G, and CCP-B to be a layer which is the base of the light control patterns CCP-R, CCP-G, and CCP-B. For example, in some embodiments, a barrier layer CAP1 may correspond to the base layer for providing the light control patterns CCP-R, CCP-G, and CCP-B. However, embodiments of the present disclosure are not limited thereto, and if (e.g., when) the barrier layer CAP1 is not provided, the low refractive layer LR may correspond to the base layer for providing the light control patterns CCP-R, CCP-G, and CCP-B. In one or more embodiments, if (e.g., when) the barrier layer CAP1 and the low refractive layer LR are not provided, the second base substrate BL may correspond to the base layer for providing the light control patterns CCP-R, CCP-G, and CCP-B.

The surface modification layer SM is arranged between the base layer and the light control patterns CCP-R, CCP-G, and CCP-B. The surface modification layer SM may be a layer improving the bonding force between the light control patterns CCP-R, CCP-G, and CCP-B and the base layer for providing the light control patterns CCP-R, CCP-G, and CCP-B. In one or more embodiments, the surface modification layer SM may be a layer improving the bonding force between the light control patterns CCP-R, CCP-G, and CCP-B and the barrier layer CAP1. In one or more embodiments, if the barrier layer CAP1 is not provided, the surface modification layer SM may be a layer improving the bonding force between the light control patterns CCP-R, CCP-G, and CCP-B and the low refractive layer LR. In one or more embodiments, if the barrier layer CAP1, the low refractive layer LR, and the color filter layer CFL are not provided, the surface modification layer DM may be a layer improving the bonding force between the light control patterns CCP-R, CCP-G, and CCP-B and the second base substrate BL.

The surface modification layer SM may be arranged on at least one side of the light control patterns CCP-R, CCP-G, and CCP-B. The surface modification layer SM may be arranged between the light control patterns CCP-R, CCP-G, and CCP-B and the base layer which is the base of the light control patterns CCP-R, CCP-G, and CCP-B. The light control patterns CCP-R, CCP-G, and CCP-B may each include one side adjacent to the base layer and the other side oppositely arranged to the one side and separated from the base layer, and the surface modification layer SM may be arranged directly on the one side of each of the light control patterns CCP-R, CCP-G, and CCP-B.

In the display device DD shown in FIG. 3 and FIG. 4A, the barrier layer CAP1 may correspond to the base layer on which the light control patterns CCP-R, CCP-G, and CCP-B are provided. The surface modification layer SM may be arranged between the barrier layer CAP1 and the light control patterns CCP-R, CCP-G, and

CCP-B, and the one side of the light control patterns CCP-R, CCP-G, and CCP-B, adjacent to the barrier layer CAP1, may make contact with the surface modification layer SM. In one or more embodiments, the surface modification layer SM may make contact with the bottom (e.g., a side) of the barrier layer CAP1 exposed by the partition wall opening part BW-OH.

In one or more embodiments, the surface modification layer SM may be arranged in the partition wall opening part BW-OH. The partition wall part BMP may include a first side adjacent to the second base substrate BL, a second side oppositely arranged to the first side, and a third side connecting the first side and the second side. The third side may correspond to the inner side portion of the partition wall part BMP. The surface modification layer SM may be arranged on one side of the base layer exposed by the partition wall opening part BW-OH. For example, in one or more embodiments, in the display device DD shown in FIG. 3 and FIG. 4A, the surface modification layer SM may be arranged on the bottom (e.g., a side) of the barrier layer CAP1 exposed by the partition wall opening part BW-OH. The surface modification layer SM may make contact with the bottom (e.g., the side) of the barrier layer CAP1 exposed by the partition wall opening part BW-OH. In one or more embodiments, at least a portion of the surface modification layer SM may be arranged on the third side corresponding to the inner side portion of the partition wall part BMP and the second side corresponding to the bottom of the partition wall part BMP. For example, as shown in FIG. 3 and FIG. 4A, in one or more embodiments, the surface modification layer SM may be arranged on the bottom (e.g., the side) of the barrier layer CAP1 exposed by the partition wall opening part BW-OH, and on the second side and the third side of the partition wall part BMP. However, embodiments of the present disclosure are not limited thereto. In one or more embodiments, the surface modification layer SM may be arranged only on one side of the base layer exposed by the partition wall opening part BW-OH and may not be arranged on the second side and the third side of the partition wall part BMP.

In one or more embodiments, the surface modification layer SM may include a coupling agent. The coupling agent included in the surface modification layer SM may be represented by Formula 1 which will be explained later. The coupling agent may be a material improving the bonding force between the light control patterns CCP-R, CCP-G, and CCP-B with an adjacent configuration making contact therewith. The coupling agent included in the surface modification layer SM may make a chemical bond with the configuration making contact with the light control patterns CCP-R, CCP-G, and CCP-B. In one or more embodiments, in the description, the coupling agent represented by Formula 1 may be referred to as a first compound (e.g., a first chemical moiety).

In the description, the term “substituted or unsubstituted” corresponds to substituted or unsubstituted with at least one substituent selected from among the group consisting of deuterium, a halogen, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In one or more embodiments, each of the exemplified substituents may be substituted or unsubstituted. For example, a biphenyl group may be interpreted as an aryl group or a phenyl group substituted with a phenyl group.

In the description, examples of a halogen may include fluorine, chlorine, bromine, or iodine.

In the description, an alkyl group may be a linear or branched type or kind. The carbon number of the alkyl group may be 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, 1-methylpentyl, 3-methylpentyl, 2-ethylpentyl, 4-methyl-2-pentyl, n-hexyl, 1-methylhexyl, 2-ethylhexyl, 2-butylhexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, and/or the like, without limitation.

In the description, an alkenyl group refers to a hydrocarbon group including one or more carbon-carbon double bonds in the middle or at the terminal of an alkyl group of 2 or more carbon atoms. The alkenyl group may be a linear chain or a branched chain. The carbon number is not specifically limited, for example, may be 2 to 30, 2 to 20 or 2 to 10. Examples of the alkenyl group may include a vinyl group, a 1-butenyl group, a 1-pentenyl group, a 1,3-butadienyl aryl group, a styrenyl group, a styrylvinyl group and/or the like, without limitation.

In the description, an aryl group refers to an optional functional group or substituent derived from an aromatic hydrocarbon ring. The aryl group may be a monocyclic aryl group or a polycyclic aryl group. The carbon number for forming rings in the aryl group may be 6 to 30, 6 to 20, or 6 to 15. Examples of the aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, and/or the like, without limitation.

In the description, a heteroaryl group may include one or more selected from among B, O, N, P, Si, and S as heteroatoms. If the heteroaryl group includes two or more heteroatoms, the two or more heteroatoms may be the same or different. The heteroaryl group may be a monocyclic heterocyclic group or polycyclic heterocyclic group. The carbon number for forming rings of the heteroaryl group may be 2 to 30, 2 to 20, or 2 to 10. Examples of the heteroaryl group may include thiophene, furan, pyrrole, imidazole, pyridine, bipyridine, pyrimidine, triazine, triazole, acridyl, pyridazine, pyrazinyl, quinoline, quinazoline, quinoxaline, phenoxazine, phthalazine, pyrido pyrimidine, pyrido pyrazine, pyrazino pyrazine, isoquinoline, indole, carbazole, N-arylcarbazole, N-heteroarylcarbazole, N-alkylcarbazole, benzoxazole, benzimidazole, benzothiazole, benzocarbazole, benzothiophene, dibenzothiophene, thienothiophene, benzofuran, phenanthroline, thiazole, isoxazole, oxazole, oxadiazole, thiadiazole, phenothiazine, dibenzosilole, dibenzofuran, and/or the like, without limitation.

In the description, the same explanation on the above-described aryl group may be applied to an arylene group except that the arylene group is a divalent group. The same explanation on the above-described heteroaryl group may be applied to a heteroarylene group except that the heteroarylene group is a divalent group.

In the description, a hydroxyl group may refer to a substituent having a “—OH” structure.

In the description, a thiol group may refer to a substituent having a “—SH” structure.

In the description, a thio group may include an alkyl thio group and/or an aryl thio group. The thio group may refer to the above-defined alkyl group or aryl group combined with a sulfur atom. Examples of the thio group include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and/or the like, without limitation.

In the description, an oxy group may refer to the above-defined alkyl group or aryl group which is combined with an oxygen atom. The oxy group may include an alkoxy group and/or an aryl oxy group. The alkoxy group may be a linear chain, a branched chain, or a cyclic ring. The carbon number of the alkoxy group is not specifically limited but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like. However, embodiments of the present disclosure are not limited thereto.

In the description, the carbon number of an amine group is not specifically limited, for example, may be 1 to 30. The amine group may include an alkyl amine group and/or an aryl amine group. Examples of the amine group include a methylamine group, a dimethylamine group, a phenylamine group, a diphenylamine group, a naphthylamine group, a 9-methyl-anthracenylamine group, and/or the like, without limitation.

In the description, a dithioic acid group may refer to a substituent having a structure of —C(═S) SR. Here, R may be hydrogen, a substituted or unsubstituted alkyl group of 1 to 30 carbon atoms, a substituted or unsubstituted aryl group of 6 to 60 ring-forming carbon atoms, or a substituted or unsubstituted heteroaryl group of 2 to 60 ring-forming carbon atoms.

In the description, a phosphine group may include an alkyl phosphine group and/or an aryl phosphine group. The phosphine group may refer to an alkyl group or an aryl group which is combined with a phosphor atom. Examples of the phosphine group may include a methylphosphine group, an ethylphosphine group, a propylphosphine group, a butylphosphine group, a pentylphosphine group, a hexylphosphine group, an octylphosphine group, a cyclopentylphosphine group, a cyclohexylphosphine group, a phenylphosphine group, a diphenylphosphine group, a triphenylphosphine group and/or the like, without limitation.

In the description, a carboxyl group may refer to a substituent represented by Structure C1.

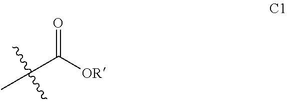

In Structure C1, R′ may be hydrogen, deuterium, a substituted or unsubstituted alkyl group of 1 to 30 carbon atoms, a substituted or unsubstituted aryl group of 6 to 60 ring-forming carbon atoms, or a substituted or unsubstituted heteroaryl group of 2 to 60 ring-forming carbon atoms.

In the description, a direct linkage may refer to a single bond.

In the description, (meth)acrylate may refer to acrylate or methacrylate.

In the description,

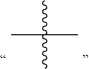

and “*------” refer to positions to be connected.

In one or more embodiments, the coupling agent contained in the surface modification layer SM may include a head part, a center part connected with the heat part, and a tail part connected with the center part. The head part may be combined with the surface of the base layer. The head part and the center part may be connected via a first connecting group or directly connected with each other without a separate connecting group. The center part and the tail part may be connected via a second connecting group or directly connected with each other without a separate connecting group. In the description, the head part may refer to a substituent represented by “*—(R¹)₂Si—” in Formula 1 which will be explained later, the center part may refer to a substituent represented by “—R²—”, and the tail part may refer to a substituent represented by “—R³”. In addition, the first connecting group may refer to a substituent represented by “—L₁—” in Formula 1 which will be explained later, and the second connecting group may refer to a substituent represented by “—L₂—”.

The head part may make a chemical bond with the surface of the base layer. The head part may be one selected from among a substituted or unsubstituted silyl group, a substituted or unsubstituted silanol group, and a substituted or unsubstituted siloxy group. In one or more embodiments, the head part may make a chemical bond with an adjacent head part in the surface modification layer SM. For example, in some embodiments, if (e.g., when) the head part includes a silanol group, the head part may make a chemical bond with an adjacent head part at the surface modification layer SM to form a Si—O—Si bond. However, embodiments of the present disclosure are not limited thereto.

The tail part may be connected with the head part via the center part. The head part may be combined with the surface of the base layer, and the tail part may be exposed in a direction away from the base layer. The tail part may include a hydrophobic substituent. In one or more embodiments, the tail part may be a substituted or unsubstituted(meth)acrylate group, a substituted or unsubstituted alkyl group of 1 to 20 carbon atoms, or a substituted or unsubstituted aryl group of 6 to 20 ring-forming carbon atoms. For example, in one or more embodiments, the tail part may be a substituted or unsubstituted alkyl group of 1 to 10 carbon atoms. Because the tail part corresponding to the terminal group of the coupling agent includes a hydrophobic substituent, the interface properties of the light control patterns CCP-R, CCP-G, and CCP-B may be controlled or selected. For example, because a hydrophobic substituent is introduced at the terminal group of the coupling agent, a photoresist composition for forming (or providing) the light control patterns CCP-R, CCP-G, and CCP-B may have excellent or suitable adhesiveness against the base layer which becomes a base. Accordingly, the layer stability of the light control patterns CCP-R, CCP-G, and CCP-B formed through a photolithography process may be improved.

The center part may be connected with the head part. The center part may connect the head part and the tail part. For example, in one or more embodiments, the coupling agent may include the head part, the center part, and the tail part, the center part may be connected with the head part, and the tail part may be connected with the center part. The center part may include a hydrophilic substituent. In one or more embodiments, the center part may include an ethylene glycol group represented by “—(O(C₂H₄))m-”. Because the center part includes the ethylene glycol group, the coupling agent may show high affinity with quantum dots QD1 and QD2, included in the light control patterns CCP-R, CCP-G, and CCP-B. Accordingly, the stability of the quantum dots QD1 and QD2, included in the light control patterns CCP-R, CCP-G, and CCP-B, may be improved, and the emission efficiency and reliability of the display device DD may be improved.

*—(R¹)₂Si—L₁—R²—L₂—R³ Formula 1

In Formula 1, R¹ may be a hydroxyl group, a substituted or unsubstituted alkoxy group of 1 to 20 carbon atoms, or a substituted or unsubstituted alkyl group of 1 to 20 carbon atoms. In one or more embodiments, R¹ may be a substituted or unsubstituted alkyl group of 1 to 10 carbon atoms. For example, in some embodiments, R¹ may be a substituted or unsubstituted methyl group.

In Formula 1, L₁ and L₂ may each independently be a direct linkage, —O—, —S—, —NHR⁴—, —O—C(═O)—, —O—C(═S)—, —O—C(═O)R⁴—, —O—C(═S)R⁴—, —C(═O)—, —C(═S)—, —C(═O)R⁴—, —C(═S)R⁴—, —C(═O) NH—, —OC(═O) NH—, —C(═O) NHR⁴—, —OC(═O) NHR⁴—, or a substituted or unsubstituted alkylene group of 1 to 20 carbon atoms. For example, in some embodiments, L₁ may be —O—C(═O)R⁴—, and L₂ may be —O—.

In Formula 1, R² may be —(O(C₂H₄))ₘ—. Here, “m” is an integer of 1 to 30. For example, in some embodiments, “m” may be an integer of 1 to 6.

In Formula 1, R³ may be a substituted or unsubstituted(meth)acrylate group, a substituted or unsubstituted alkyl group of 1 to 20 carbon atoms, or a substituted or unsubstituted aryl group of 6 to 30 ring-forming carbon atoms. In one or more embodiments, R³ may be a substituted or unsubstituted alkyl group of 1 to 10 carbon atoms. For example, in some embodiments, R³ may be a substituted or unsubstituted methyl group.

In Formula 1, R⁴ may be a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In one or more embodiments, R⁴ may be a substituted or unsubstituted alkylene group of 1 to 10 carbon atoms. For example, in some embodiments, R⁴ may be a substituted or unsubstituted methylene group.

In Formula 1, “*------” is a position connected with the base layer.

In one or more embodiments, the coupling agent represented by Formula 1 may be represented by Formula 2.

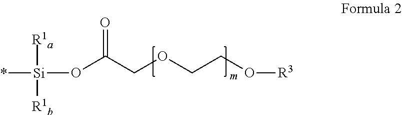

In Formula 2, R¹ₐ and R¹_{b} may each independently be a hydroxyl group, a substituted or unsubstituted alkoxy group of 1 to 20 carbon atoms, or a substituted or unsubstituted alkyl group of 1 to 20 carbon atoms. In one or more embodiments, R¹ₐ and R¹_{b} may each independently be a substituted or unsubstituted alkyl group of 1 to 10 carbon atoms. For example, in some embodiments, R¹ₐ and R¹_{b} may each be a substituted or unsubstituted methyl group.

In Formula 2, the same contents explained in Formula 1 may be applied for R³ and “m”.

Referring to FIG. 3 and FIG. 4A again, the light control patterns CCP-R, CCP-G, and CCP-B are respectively arranged in the partition wall opening part BW-OH. The light control patterns CCP-R, CCP-G, and CCP-B may be arranged under the surface modification layer SM. The top of the light control patterns CCP-R, CCP-G, and CCP-B may make contact with the bottom of the surface modification layer SM.

In one or more embodiments, at least a portion of (e.g., at least one selected from among) the light control patterns CCP-R, CCP-G, and CCP-B may change the optical properties of the source light. In one or more embodiments, the first and second light control patterns CCP-R and CCP-G may change the optical properties of the source light.

In one or more embodiments, at least a portion of (e.g., at least one selected from among) the light control patterns CCP-R, CCP-G, and CCP-B may include a quantum dot for changing the optical properties of the source light. In some embodiments, the first and second light control patterns CCP-R and CCP-G may include the quantum dot for changing the source light into light having another wavelength. In one or more embodiments, each of the first and second light control patterns CCP-R and CCP-G may include the quantum dot. The first light control pattern CCP-R overlapping with the first pixel area PXA-R may include a first quantum dot QD1 converting the source light into first light. The second light control pattern CCP-G overlapping with the second pixel area PXA-G may include a second quantum dot QD2 converting the source light into second light. In one or more embodiments, the first light may be light having a central wavelength in a wavelength range of about 625 nm to about 675 nm, the second light may be light having a central wavelength in a wavelength range of about 500 nm to about 570 nm, and third light which is the source light may be light having a central wavelength in a wavelength range of about 410 nm to about 480 nm.

In the description, the quantum dot refers to the crystal of a semiconductor compound. The quantum dot may be to emit light in one or more suitable emission wavelengths according to a size of the crystal. The quantum dot may be to emit light in one or more suitable emission wavelengths by controlling an element ratio in a quantum dot compound.

The diameter of the quantum dot may be, for example, about 1 nm to about 10 nm. In the present disclosure, when quantum dot, quantum dots, or quantum dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The quantum dot may be synthesized by a chemical bath deposition, a metal organic chemical vapor deposition, a molecular beam epitaxy, or a similar process therewith.

The chemical bath deposition is a method of growing quantum dot particle crystal after mixing an organic solvent and a precursor material of a quantum dot. During the growth of the crystal, the organic solvent naturally plays the role of a dispersant coordinated at the surface of the quantum dot crystal and may control the growth of the crystal. Accordingly, the chemical bath deposition is more favorable than a vapor deposition method such as a metal organic chemical vapor deposition (MOCVD) and/or a molecular beam epitaxy (MBE), and may control the growth of the quantum dot particle through a relatively low cost process.

In one or more embodiments, the quantum dot may have a core, the core of the quantum dot may be selected from among a II-VI group compound, a III-V group compound, a III-VI group compound, a I-III-VI group compound, a IV-VI group compound, a IV group element, a IV group compound, and the combinations thereof.

The II-VI group compound may be selected from among the group consisting of: a binary compound selected from among the group consisting of CdSe, CdTe, CdS, ZnS, ZnSe, ZnTe, ZnO, HgS, HgSe, HgTe, MgSe, MgS, and the mixtures thereof; a ternary compound selected from among the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and the mixtures thereof; and a quaternary compound selected from among the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and the mixtures thereof. In one or more embodiments, the II-VI group compound may further include a metal in group I and/or an element in group IV. A I-II-VI group compound may be selected from among CuSnS and CuZnS, and a II-IV-VI group compound may be ZnSnS, and/or the like. A I-II-IV-VI group compound may be selected from among a quaternary compound selected from among the group consisting of Cu₂ZnSnS₂, Cu₂ZnSnS₄, Cu₂ZnSnSe₄, Ag₂ZnSnS₂ and the mixtures thereof.

The III-VI group compound may include a binary compound such as In₂S₃ and/or In₂Se₃, a ternary compound such as InGaSs and/or InGaSe₃, or combinations thereof.

The I-III-VI group compound may be selected from among a ternary compound selected from among the group consisting of AgInS, AgInS₂, CulnS, CulnS₂, AgGaS₂, CuGaS₂, CuGaO₂, AgGaO₂, AgAIO₂ and the mixtures thereof, and a quaternary compound such as AgInGaS₂ and/or CulnGaS₂.

The III-V group compound may be selected from among the group consisting of a binary compound selected from among the group consisting of GaN, GaP, GaAs, GaSb, AlN, AIP, AIAs, AISb, InN, InP, InAs, InSb, and the mixtures thereof, a ternary compound selected from among the group consisting of GaNP, GaNAs, GaNSb, GaPAs, GaPSb, AlNP, AlNAs, AlNSb, AIPAS, AIPSb, InGaP, InAIP, InNP, InNAs, InNSb, InPAs, InPSb, and the mixtures thereof, and a quaternary compound selected from among the group consisting of GaAINP, GaAINAs, GaAINSb, GaAIPAs, GaAIPSb, GalnNP, GalnNAs, GalnNSb, GalnPAs, GalnPSb, InAINP, InAINAs, InAINSb, InAIPAs, InAIPSb, and the mixtures thereof. In one or more embodiments, the III-V group compound may further include a II group metal. For example, InZnP, and/or the like may be selected as a III-II-V group compound.

The IV-VI group compound may be selected from among the group consisting of a binary compound selected from among the group consisting of SnS, SnSe, SnTe, PbS, PbSe, PbTe, and the mixtures thereof, a ternary compound selected from among the group consisting of SnSeS, SnSeTe, SnSTe, PbSeS, PbSeTe, PbSTe, SnPbS, SnPbSe, SnPbTe, and the mixtures thereof, and a quaternary compound selected from among the group consisting of SnPbSSe, SnPbSeTe, SnPbSTe, and the mixtures thereof.

The II-IV-V group compound may be selected from among a ternary compound selected from among the group consisting of ZnSnP, ZnSnP₂, ZnSnAs₂, ZnGeP₂, ZnGeAs₂, CdSnP₂, CdGeP₂ and the mixtures thereof.

The IV group element may be selected from among the group consisting of Si, Ge, and mixtures thereof. The IV group compound may be a binary compound selected from among the group consisting of SiC, SiGe and mixtures thereof.

Each element included in a polynary compound such as a binary compound, a ternary compound, and a quaternary compound may be present at substantially uniform or non-uniform concentration in a particle. For example, the formulae of the quantum dots refer to the types (kinds) of elements included in the compounds, and an element ratio in the compound may be different. For example, AgInGaS₂ may refer to AglnₓGa₁₋ₓS₂ (x is a real number between 0 and 1).

For example, each element in the binary compound, the ternary compound, or the quaternary compound may be present at substantially uniform concentration in a particle or may be present at a partially different concentration distribution state in substantially the same particle. In one or more embodiments, a core/shell structure in which one quantum dot wraps another quantum dot may be desirable. In the core/shell structure, a concentration gradient in which the concentration of an element present in the shell is decreased toward the center, may be present.

In some embodiments, the quantum dot may have the core-shell structure including a core including a nanocrystal and a shell wrapping the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may include a metal or non-metal oxide, a semiconductor compound, or combinations thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, CO₃O₄, and/or NiO, and/or a ternary compound such as MgAl₂O₄, CoFe₂O₄, NiFe₂O₄, and/or CoMn₂O₄, but embodiments of the present disclosure are not limited thereto.

Also, the semiconductor compound suitable as a shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AISb, and/or the like, but embodiments of the present disclosure are not limited thereto.

The quantum dot may have a full width of half maximum (FWHM) of emission spectrum of about 45 nm or less, about 40 nm or less, or about 30 nm or less. Within this range, color purity or color reproducibility of the quantum dot may be improved. In one or more embodiments, light emitted via such a quantum dot is emitted in all directions, and light view angle properties may be improved.

In one or more embodiments, the shape of the quantum dot may be the shape generally utilized in the art, without specific limitation. For example, the shape of spherical nanoparticle, pyramidal nanoparticle, multi-arm nanoparticle, or cubic nanoparticle, nanotube, nanowire, nanofiber, nanoplate particle, and/or the like may be utilized.

By controlling the size of the quantum dot or by controlling the element ratio in the quantum dot compound, the energy band gap of the quantum dot may be controlled or selected, and one or more suitable wavelength bands of light may be obtained from a quantum dot emission layer. Accordingly, by utilizing such a quantum dot (utilizing quantum dots having different sizes or controlling an element ratio in a quantum dot compound differently), a light emitting element emitting one or more suitable wavelengths of light may be accomplished. For example, the size of the quantum dots and/or the element ratio in the quantum dot compound may be controlled or selected to enable the quantum dots to emit red, green, and/or blue light.

In one or more embodiments, the quantum dots may be provided to combine one or more suitable emission colors to emit white light.

The quantum dot may further include a ligand. In one or more embodiments, the quantum dot may include a core, a shell wrapping the core, and a ligand bonded to a surface of the shell. The ligand may include a hydrophilic group. In one or more embodiments, the quantum dot includes a ligand including a hydrophilic group and attached to the surface of the shell, and may have modified surface properties.

In one or more embodiments, the ligand may include an ethylene glycol group. The ethylene glycol group is a hydrophilic group and may play the role of increasing dispersibility when dispersing quantum dots in a solvent. In one or more embodiments, the ligand may include a polyethylene glycol group.

In one or more embodiments, the ligand may include a first quantum dot head part, a first quantum dot connecting part connected with the first quantum dot head part, and a first quantum dot tail part connected with the first quantum dot connecting part. The first quantum dot head part may be combined with the surface of the shell. The ligand may be combined with a cation provided at the surface of the shell. If the first quantum dot head part includes one functional group for the combination with the surface of the shell, the ligand may be a monodentate ligand. If the first quantum dot head part includes two functional groups for the combination with the surface of the shell, the ligand may be a bidentate ligand. The first quantum dot head part includes a functional group for the combination with the surface of the shell of the quantum dot, and the ligand may be effectively combined with the quantum dot.

In one or more embodiments, the first quantum dot head part may be an electron donating head part. The first quantum dot head part may have a structure including an anion in the functional group. In one or more embodiments, the first quantum dot head part may be one of a hydroxyl group, a thiol group, a dithioic acid group, a phosphine group, a catechol group, an amine group, or a carboxylic acid group.

The ligand may include the first quantum dot tail part. The first quantum dot tail part may be connected with the first quantum dot head part. In one or more embodiments, the first quantum dot head part may be combined with the surface of the shell, and the first quantum dot tail part may be exposed to the outside of the quantum dot. In one or more embodiments, the first quantum dot tail part may include a hydroxyl group, a thiol group, a substituted or unsubstituted oxy group, a substituted or unsubstituted thio group, a substituted or unsubstituted(meth)acrylate group, a substituted or unsubstituted alkyl group of 1 to 30 carbon atoms, or a substituted or unsubstituted alkenyl group of 2 to 30 carbon atoms. For example, in some embodiments, the first quantum dot tail part may be a substituted or unsubstituted methyl group, a substituted or unsubstituted methoxy group, or a substituted or unsubstituted acrylate group.

The ligand may include the first quantum dot connecting part. The first quantum dot connecting part of the ligand may be connected with the first quantum dot head part. The first quantum dot connecting part may connect the first quantum dot head part and the first quantum dot tail part. For example, in one or more embodiments, the ligand may include the first quantum dot head part, the first quantum connecting part, and the first quantum dot tail part, the first quantum dot connecting part may be connected with the first quantum dot head part, and the first quantum dot tail part may be connected with the first quantum dot connecting part. However, embodiments of the present disclosure are not limited thereto, and the first quantum dot tail part may not be provided in the ligand.

In one or more embodiments, the ligand may include an ethylene glycol group. The first quantum dot connecting part of the ligand may include an ethylene glycol group. In the description, the “ethylene glycol group” may refer to a residual group having —(OC₂H₄)ₙ—. Here, “n” is an integer of 1 to 30. The first quantum dot connecting part of the ligand may further include a substituted or unsubstituted alkylene group of 1 to 30 carbon atoms in addition to the ethylene glycol group. The alkylene group may connect the ethylene glycol group with the first quantum dot head part, or the ethylene glycol group with the first quantum dot tail part.

In one or more embodiments, the ligand may be represented by Formula L.

R_{z}—Lₐ—(OCH₂CH₂)ₙ—L_{b}-R_{y} Formula L

In Formula L, R_{z} may be a hydroxyl group, a thiol group, a carboxylic acid group, a dithioic acid group, a phosphine group, a catechol group, or an amine group. For example, in some embodiments, R_{z} may be a thiol group or a carboxylic acid group.

In Formula L, R_{y} may be a hydroxyl group, a thiol group, a substituted or unsubstituted oxy group, a substituted or unsubstituted thio group, a substituted or unsubstituted(meth)acrylate group, a substituted or unsubstituted alkyl group of 1 to 30 carbon atoms, or a substituted or unsubstituted alkenyl group of 2 to 30 carbon atoms. For example, in some embodiments, R_{y} may be a substituted or unsubstituted methyl group or a substituted or unsubstituted acrylate group.

In Formula L, Lₐ and L_{b} may each independently be a direct linkage or a substituted or unsubstituted alkylene group of 1 to 30 carbon atoms.

In Formula L, “n” may be an integer of 1 to 30.

In one or more embodiments, in Formula L, R_{z} may correspond to the above-described head part, R_{y} may correspond to the above-described tail part, and “—Lₐ—(OCH₂CH₂) n-L_{b}-” may correspond to the above-described connecting part.

Referring to FIG. 4A again, in one or more embodiments, the quantum dot contained in the first light control pattern CCP-R overlapping with the first pixel area PXA-R may have red light emitting color. The quantum dot contained in the second light control pattern CCP-G overlapping with the second pixel area PXA-G may have green light emitting color.

If (e.g., when) the particle size of the quantum dot decreases, the quantum dot may be to emit light in a short wavelength range. For example, in the quantum dots having the same type or kind of the core, the particle size of the quantum dot emitting green light may be smaller than the particle size of the quantum dot emitting red light. In one or more embodiments, in the quantum dots having the same type of king of the core, the particle size of the quantum dot emitting blue light may be smaller than the particle size of the quantum dot emitting green light. However, embodiments of the present disclosure are not limited thereto, and even in the quantum dots having the same type or kind of the core, the particle size may be controlled or selected according to the forming material of the shell and the thickness of the shell.

In one or more embodiments, if (e.g., when) the quantum dots have one or more suitable light emitting colors including blue, red, green, and/or the like, the materials of the cores of the quantum dots having different light emitting colors may be different from each other.

In one or more embodiments, the light control patterns CCP-R, CCP-G, and CCP-B may further include a scatterer. The first light control pattern CCP-R may include a first quantum dot QD1 converting the source light into red light and the scatterer scattering light. The second light control pattern CCP-G may include a second quantum dot QD2 converting the source light into green light and the scatterer scattering light. The third light control pattern CCP-B may not include (e.g., may exclude) a quantum dot but include the scatterer scattering light. However, embodiments of the present disclosure are not limited thereto, for example, the third light control pattern CCP-B may include a third quantum dot and the scatterer scattering light.

The scatterer may be an inorganic particle. For example, in one or more embodiments, the scatterer may include at least one selected from among TiO₂, ZnO, Al₂O₃, SiO₂, and hollow silica. In some embodiments, the scatterer may include one selected from among TiO₂, ZnO, Al₂O₃, SiO₂, and hollow silica, or may be a mixture of two or more materials of (e.g., selected from among) TiO₂, ZnO, Al₂O₃, SiO₂, and hollow silica.

The light control patterns CCP-R, CCP-G, and CCP-B may include a base resin dispersing the quantum dots and/or the scatterer. The base resin may be a medium in which the quantum dots and the scatterer are dispersed, and may generally be composed of one or more suitable resin compositions which may be referred to as binders. For example, the base resin may be an acryl-based resin, a urethane-based resin, a silicon-based resin, an epoxy-based resin, and/or the like. The base resin may be a transparent resin.

In one or more embodiments, at least one selected from among the light control patterns CCP-R, CCP-G, and CCP-B may be formed by a photolithography process. For example, all the first to third light control patterns CCP-R, CCP-G, and CCP-B may be formed by the photolithography process. However, embodiments of the present disclosure are not limited thereto, for example, in some embodiments, one or two selected from among the first to third light control patterns CCP-R, CCP-G, and CCP-B may be formed by the photolithography process, and the remainder may be formed by an ink jet process.

If (e.g., when) the light control patterns CCP-R, CCP-G, and CCP-B include quantum dots QD1 and QD2, the amounts of the quantum dots QD1 and QD2 may each be about 50 wt % to about 70 wt % on the basis of the total weight of the corresponding light control patterns CCP-R, CCP-G, and CCP-B. For example, in one or more embodiments, if (e.g., when) the first light control pattern CCP-R includes the first quantum dot QD1, the weight of the first quantum dot QD1 may be about 50 wt % to about 70 wt % on the basis of the total weight of the first light control pattern CCP-R. In one or more embodiments, if (e.g., when) the second light control pattern CCP-G includes the second quantum dot QD2, the weight of the second quantum dot QD2 may be about 50 wt % to about 70 wt % on the basis of the total weight of the second light control pattern CCP-G. In one or more embodiments, if (e.g., when) the third light control pattern CCP-B includes the third quantum dot, the weight of the third quantum dot may be about 50 wt % to about 70 wt % on the basis of the total weight of the third light control pattern CCP-B.

If (e.g., when) the amount of the quantum dots QD1 and QD2 are less than about 50 wt %, the emission efficiency of the light control patterns CCP-R, CCP-G, and CCP-B may be deteriorated due to the relatively low quantum dot contents. If (e.g., when) the amounts of the quantum dots QD1 and QD2 are greater than about 70 wt %, the photo sensitivity of the photoresist composition may be reduced in a photolithography process, and a dissolution rate in a developing solution in a developing process may be inhibited or reduced. If (e.g., when) the amounts of the quantum dots QD1 and QD2 satisfy the above-described ranges, the light control patterns CCP-R, CCP-G, and CCP-B may show high emission efficiency, the photo sensitivity in a photolithography process may be improved, and excellent or suitable pattern profile may be obtained.

The light control layer CCL includes a barrier layer CAP1 arranged at one side of the light control patterns CCP-R, CCP-G, and CCP-B. The barrier layer CAP1 may play the role of preventing or reducing the penetration of humidity and/or oxygen (hereinafter, referred to as “humidity/oxygen”) and improving the optical properties of the light control member CCM by controlling a refractive index. The barrier layer CAP1 may be arranged at one side of the top or at one side of the bottom of the first light control pattern CCP-R to block or reduce the exposure of the light control patterns CCP-R, CCP-G, and CCP-B to humidity/oxygen, for example, to block or reduce the exposure of the quantum dots included in the light control patterns CCP-R, CCP-G, and CCP-B to humidity/oxygen. The barrier layer CAP1 may also protect the light control patterns CCP-R, CCP-G, and CCP-B from external impact.

In one or more embodiments, the barrier layer CAP1 may be separately arranged from the display element layer DP-LED with the light control patterns CCP-R, CCP-G, and CCP-B therebetween. In one or more embodiments, the light control layer CCL may include an additional barrier layer CAP2 arranged between the light control patterns CCP-R, CCP-G, and CCP-B and the display element layer DP-LED. The additional barrier layer CAP2 may cover the bottom of the light control patterns CCP-R, CCP-G, and CCP-B adjacent to the display element layer DP-LED. In the description, the “top” may be a surface positioned at an upper portion based on the third direction DR3, and the “bottom” may be a surface positioned at a lower portion based on the third direction DR3.

The barrier layer CAP1 may cover the one side of a partition wall part BMP adjacent to a low refractive layer LR. In one or more embodiments, the barrier layer CAP1 may cover a portion of the top surface of the surface modification layer SM. The barrier layer CAP1 may be arranged directly under the low refractive layer LR. The additional barrier layer CAP2 may be arranged following the partition wall part BMP and the light control patterns CCP-R, CCP-G, and CCP-B. In some embodiments, the additional barrier layer CAP2 may be arranged directly on a filling layer FML.

The barrier layer CAP1 and the additional barrier layer CAP2 may be formed by including an inorganic material. In the display device DD of one or more embodiments, the barrier layer CAP1 and the additional barrier layer CAP2 may each independently include at least one selected from among silicon oxide, silicon nitride, and silicon oxynitride. In some embodiments, both the barrier layer CAP1 and the additional barrier layer CAP2 may include silicon oxynitride. However, embodiments of the present disclosure are not limited thereto, for example, in some embodiments, the barrier layer CAP1 arranged on the light control patterns CCP-R, CCP-G, and CCP-B may include silicon oxynitride, and the additional barrier layer CAP2 arranged under the light control patterns CCP-R, CCP-G, and CCP-B may include silicon nitride. However, embodiments of the present disclosure are not limited thereto.

On the light control layer CCL, the color filter layer CFL is arranged. The color filter layer CFL may include at least one color filter. The color filter transmits light in a specific wavelength range and blocks light in other than the wavelength range. A first color filter CF1 of the first pixel area PXA-R may be to transmit red light and block or reduce green light and blue light. A second color filter CF2 of the second pixel area PXA-G may be to transmit green light and block or reduce red light and blue light. A third color filter CF3 of the third pixel area PXA-B may be to transmit blue light and block or reduce red light and green light.

The color filters CF1, CF2, and CF3 may include a base resin and a dye and/or pigment dispersed in the base resin. The base resin is a medium in which the dye and/or pigment are dispersed, and may be composed of one or more suitable resin compositions which may be generally referred to as binders.

The first color filter CF1 may have a substantially uniform thickness in the first pixel area PXA-R. Light converted from the source light which is blue light into red light via the first light control pattern CCP-R, may be provided to the outside in substantially uniform luminance in the first pixel area PXA-R. The second color filter CF2 may have a substantially uniform thickness in the second pixel area PXA-G. Light converted from the source light which is blue light into green light via the second light control pattern CCP-G, may be provided to the outside in substantially uniform luminance in the second pixel area PXA-G. The third color filter CF3 may have a substantially uniform thickness in the third pixel area PXA-B. Blue light transmitted through the third light control pattern CCP-B may be provided to the outside in substantially uniform luminance in the third pixel area PXA-B.

The light control member CCM includes the low refractive layer LR. The low refractive layer LR may be arranged between the light control layer CCL and the color filter layer CFL. The low refractive layer LR may be arranged on the light control layer CCL to block or reduce the exposure of the light control patterns CCP-R, CCP-G, and CCP-B to humidity/oxygen. In one or more embodiments, the low refractive layer LR may be arranged between the light control patterns CCP-R, CCP-G, and CCP-B and the color filters CF1, CF2, and CF3, and may play the role of an optical functional layer for increasing light extraction efficiency or preventing or reducing the incidence of reflected light into the light control layer CCL. The low refractive layer LR may be a layer having a smaller refractive index in contrast to or relative to an adjacent layer.

The low refractive layer LR may include at least one inorganic layer. For example, in one or more embodiments, the low refractive layer LR may be formed by including one or more selected from among silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride, or a metal thin film securing light transmittance. However, embodiments of the present disclosure are not limited thereto, for example, in some embodiments, the low refractive layer LR may include an organic layer. In one or more embodiments, the low refractive layer LR may have, for example, a structure in which multiple hollow particles are dispersed in an organic polymer resin. The low refractive layer LR may be composed of a single layer or multiple layers.

In one or more embodiments, the display device DD may further include a second base substrate BL arranged on the color filter layer CFL. The second base substrate BL may be a member providing a base surface on which the color filter layer CFL, the low refractive layer LR, the light control layer CCL, and/or the like are arranged. The second base substrate BL may be a glass substrate, a metal substrate, a plastic substrate, and/or the like. However, embodiments of the present disclosure are not limited thereto, for example, the second base substrate BL may be an inorganic layer, an organic layer, or a composite material layer. In one or more embodiments, the second base substrate BL may not be provided.

In one or more embodiments, an anti-reflection layer may be arranged on the second base substrate BL. The anti-reflection layer may be a layer reducing the reflectivity of external light incident from the outside. The anti-reflection layer may be a layer selectively transmitting light emitted from the display panel DP. In one or more embodiments, the anti-reflection layer may be a single layer including a dye and/or pigment dispersed in a base resin. The anti-reflection layer may be provided as a substantially continuous one layer entirely overlapping with the first to third pixel areas PXA-R, PXA-B, and PXA-G.

In one or more embodiments, the anti-reflection layer may not include (e.g., may exclude) a polarization layer. Accordingly, light passed through the anti-reflection layer and incident toward the display element layer DP-LED may be unpolarized light. The display element layer DP-LED may receive unpolarized light from an upper portion of the anti-reflection layer.

The display device DD of one or more embodiments may include a lower panel including the display element layer DP-LED and an upper panel (the light control member CCM) including the light control layer CCL and the color filter layer CFL, and, in one or more embodiments, a filling layer FML may be arranged between the lower panel and the upper panel CCM. In one or more embodiments, the filling layer FML may fill up a gap between the display element layer DP-LED and the light control layer CCL. The filling layer FML may be arranged directly on the encapsulating layer TFE, and the additional barrier layer CAP2 may be arranged directly on the filling layer FML. The bottom of the filling layer FML may make contact with the top of the encapsulating layer TFE, and the top of the filling layer FML may make contact with the bottom of the additional barrier layer CAP2.

The filling layer FML may play the role of a buffering agent between the display element layer DP-LED and the light control layer CCL. In one or more embodiments, the filling layer FML may play the role of absorbing impact and increase the strength of the display device DD. The filling layer FML may be formed utilizing a filling resin including a polymer resin. For example, in some embodiments, the filling layer FML may be formed from a filling layer resin including an acryl-based resin or an epoxy-based resin.

The filling layer FML may be a configuration separated from the encapsulating layer TFE arranged thereunder and the additional barrier layer CAP2 arranged thereon, and may be formed by a separate process operation. In one or more embodiments, the filling layer FML may be formed utilizing a different material from the encapsulating layer TFE and the additional barrier layer CAP2.

In one or more embodiments, the display panel DP may include a first base substrate BS and a circuit element layer DP-CL arranged on the first base substrate BS. The circuit element layer DP-CL may be arranged on the first base substrate BS. The circuit element layer DP-CL may include an insulating layer, a semiconductor pattern, a conductive pattern, and a signal line. An insulating layer, a semiconductor layer, and a conductive layer may be formed on the first base substrate BS by the method of coating, deposition, and/or the like, and then, the insulating layer, the semiconductor layer, and the conductive layer may be selectively patterned through multiple photolithography processes. After that, the semiconductor pattern, the conductive pattern, and the signal line included in the circuit element layer DP-CL may be formed. In one or more embodiments, the circuit element layer DP-CL may include a transistor, a buffer layer, and multiple insulating layers.

The light emitting element LED according to one or more embodiments may include a first electrode EL1, a second electrode EL2 oppositely arranged to the first electrode EL1, and an emission layer EML arranged between the first electrode EL1 and the second electrode EL2. The emission layer EML included in the light emitting element LED may include an organic light emitting material or a quantum dot as a light emitting material. The light emitting element LED may further include a hole control layer HTR and an electron control layer ETR. In one or more embodiments, the light emitting element LED may further include a capping layer arranged on the second electrode EL2.

In one or more embodiments, a pixel definition layer PDL may be arranged on the circuit element layer DP-CL and may cover a portion of the first electrode EL1. In the pixel definition layer PDL, a light emitting opening part OH is defined. The light emitting opening part OH of the pixel definition layer PDL may expose at least a portion of the first electrode EL1. In these embodiments, light emitting areas EA1, EA2, and EA3 are defined to correspond to some areas of the first electrode EL1 exposed by the light emitting opening part OH.

The display element layer DP-LED may include a first light emitting area EA1, a second light emitting area EA2, and a third light emitting area EA3. The first light emitting area EA1, the second light emitting area EA2, and the third light emitting area EA3 may be areas divided by the pixel definition layer PDL. The first light emitting area EA1, the second light emitting area EA2, and the third light emitting area EA3 may correspond to the first pixel area PXA-R, the third pixel area PXA-B, and the second pixel area PXA-G, respectively.

The light emitting areas EA1, EA2, and EA3 may overlap with the pixel areas PXA-R, PXA-B, and PXA-G, respectively, and may not overlap with a bank well area BWA. When viewed on a plane, the areas of the pixel areas PXA-R, PXA-B, and PXA-G, separated by the partition wall part BMP, may be greater than the areas of the light emitting areas EA1, EA2, and EA3, respectively, separated by the pixel definition layer PDL.

In the light emitting element LED, the first electrode EL1 is arranged on the circuit element layer DP-CL. The first electrode EL1 may be an anode or a cathode. In one or more embodiments, the first electrode EL1 may be a pixel electrode. The first electrode EL1 may be a transmissive electrode, a transflective electrode, or a reflective electrode.

The hole control layer HTR may be arranged between the first electrode and the emission layer EML. The hole control layer HTR may include at least one selected from among a hole injection layer, a hole transport layer, and an electron blocking layer. The hole control layer HTR may be arranged as a common layer to overlap with the entire of the light emitting areas EA1, EA2, and EA3 and the pixel definition layer PDL which separates the light emitting areas EA1, EA2, and EA3. However, embodiments of the present disclosure are not limited thereto, for example, the hole control layer HTR may be patterned and provided so as to be separated and arranged corresponding to the light emitting areas EA1, EA2, and EA3.

The emission layer EML is arranged on the hole control layer HTR. In one or more embodiments, the emission layer EML may be provided as a common layer to overlap with the entire of the light emitting areas EA1, EA2, and EA3 and the pixel definition layer PDL which separates the light emitting areas EA1, EA2, and EA3. In one or more embodiments, the emission layer EML may be to emit blue light. The emission layer EML may overlap with the entire of the hole control layer HTR and the electron control layer ETR.

However, embodiments of the present disclosure are not limited thereto, for example, in one or more embodiments, the emission layer EML may be arranged in the light emitting opening part OH. For example, the emission layer EML may be separately formed to correspond to the light emitting areas EA1, EA2, and EA3, which are separated by the pixel definition layer PDL. The emission layer EML separately formed to correspond to the light emitting areas EA1, EA2, and EA3 may be to emit blue light or emit light having different wavelength ranges.

The emission layer EML may have a single layer formed utilizing a single material, a single layer formed utilizing multiple different materials, or a multilayer structure having multiple layers formed utilizing multiple different materials. The emission layer EML may include a fluorescence and/or a phosphorescence material. In the light emitting element of one or more embodiments, the emission layer EML may include an organic light emitting material, a metal organic complex, or a quantum dot as a light emitting material. In one or more embodiments, in FIG. 3 and FIG. 4A, the light emitting element LED including one emission layer EML is shown as an example, the light emitting element LED of one or more embodiments may include multiple light emitting stacks each including at least one emission layer.

The electron control layer ETR may be arranged between the emission layer EML and the second electrode EL2. The electron control layer ETR may include at least one selected from among an electron injection layer, an electron transport layer, and a hole blocking layer. Referring to FIG. 4A, the electron control layer ETR may be arranged as a common layer overlapping with the entire of the light emitting areas EA1, EA2, and EA3 and the pixel definition layer PDL which separates the light emitting areas EA1, EA2 and EA3. However, embodiments of the present disclosure are not limited thereto, for example, in some embodiments, the electron control layer ETR may be patterned and provided so as to be separated and arranged to correspond to each of the light emitting areas EA1, EA2, and EA3.

The second electrode EL2 may be provided on the electron control layer ETR. The second electrode EL2 may be a common electrode. The second electrode EL2 may be a cathode or an anode, but embodiments of the present disclosure are not limited thereto. For example, if the first electrode EL1 is an anode, the second electrode EL2 may be a cathode, and if the first electrode EL1 is a cathode, the second electrode EL2 may be an anode. The second electrode EL2 may be a transmissive electrode, a transflective electrode, or a reflective electrode.

In one or more embodiments, an encapsulating layer TFE may be arranged on the light emitting element LED. For example, in one or more embodiments, the encapsulating layer TFE may be arranged on the second electrode EL2. In one or more embodiments, if the light emitting element LED includes a capping layer, the encapsulating layer TFE may be arranged on the capping layer. In some embodiments, the encapsulating layer TFE may include at least one organic layer and at least one inorganic layer as described above, and the inorganic layers and the organic layers may be alternately arranged.

The display device DD of one or more embodiments may include a light control member CCM arranged on the display element layer DP-LED. The light control member CCM may include a light control layer CCL, a color filter layer CFL, and a second base substrate BL.

The light control layer CCL may include a light converter. The light converter may be a quantum dot and/or a phosphor. The light converter may convert the wavelength of light provided and then, emit. For example, in one or more embodiments, the light control layer CCL may be a layer at least partially including a quantum dot and/or a phosphor.

In one or more embodiments, the light control layer CCL may include multiple light control patterns CCP-R, CCP-B, and CCP-G. The light control patterns CCP-R, CCP-B, and CCP-G may be separated from each other. The light control patterns CCP-R, CCP-B, and CCP-G may be separately arranged by a partition wall part BMP. The light control patterns CCP-R, CCP-B, and CCP-G may be arranged in a partition wall opening part BW-OH defined in the partition wall part BMP. However, embodiments of the present disclosure are not limited thereto. In FIG. 4A, the partition wall part BMP is shown to have a square shape on a cross-section and not to overlap with the light control patterns CCP-R, CCP-B, and CCP-G, but, in some embodiments, the edges of the light control patterns CCP-R, CCP-B, and CCP-G may overlap with at least a portion of the partition wall part BMP. In some embodiments, the partition wall part BMP may have a trapezoid shape on a cross-section. The partition wall part BMP may have a shape having increasing width toward the display element layer DP-LED.

The light control layer CCL may include a first light control pattern CCP-R including a first quantum dot QD1 converting source light provided from the light emitting element LED into first light, a second light control pattern CCP-G including a second quantum dot QD2 converting the source light into second light, and a third light control pattern CCP-B transmitting the source light.

In one or more embodiments, the first light control pattern CCP-R provides red light which is the first light, the second light control pattern CCP-G provides green light which is the second light, and the third light control pattern CCP-B may be to transmit and provide blue light which is the source light provided from the light emitting element LED. For example, in one or more embodiments, the first quantum dot may be a red quantum dot to emit red light, and the second quantum dot may be a green quantum dot to emit green light.

In the display device DD, the light control member CCM may include a color filter CFL arranged on the light control layer CCL. The color filter layer CFL may include color filters CF1, CF2, and CF3. In one or more embodiments, the color filter layer CFL may include a first color filter CF1 transmitting the first light, a second color filter CF2 transmitting the second light, and a third color filter CF3 transmitting the source light. In one or more embodiments, the first color filter CF1 may be a red filter, the second color filter CF2 may be a green filter, and the third color filter CF3 may be a blue filter.

Each of the filters CF1, CF2, and CF3 may include a polymer photosensitive resin and a coloring agent. In one or more embodiments, the first color filter CF1 may include a red coloring agent, the second color filter CF2 may include a green coloring agent, and the third color filter CF3 may include a blue coloring agent. In one or more embodiments, the first color filter CF1 may include a red pigment and/or a red dye, the second color filter CF2 may include a green pigment and/or a green dye, and the third color filter CF3 may include a blue pigment and/or a blue dye.

The first to third color filters CF1, CF2, and CF3 may be correspondingly arranged to the first pixel area PXA-R, the second pixel area PXA-G, and the third pixel area PXA-B, respectively. In one or more embodiments, the first to third color filters CF1, CF2 and CF3 may be correspondingly arranged to the first light control pattern to the third light control pattern CCP-R, CCP-G, and CCP-B, respectively.

In one or more embodiments, corresponding to a peripheral area NPXA arranged among the pixel areas PXA-R, PXA-G, and PXA-B, multiple color filters CF1, CF2, and CF3 may be arranged in an overlapping mode. Multiple color filters CF1, CF2, and CF3 may be arranged in an overlapping mode in a third direction DR3 which is a thickness direction to divide the boundary among adjacent light emitting areas PXA-R, PXA-G and PXA-B. In one or more embodiments, the color filter layer CFL separates the boundary among adjacent color filters CF1, CF2 and CF3 and may include a light blocking part. The light blocking part may be formed as a blue filter or may be formed by including an organic light blocking material and/or an inorganic light blocking material, including a black pigment and/or a black dye.

In one or more embodiments, the light control member CCM may include a low refractive layer LR arranged between the light control layer CCL and the color filter layer CFL. The low refractive layer LR may be arranged between the light control patterns CCP-R, CCP-G, and CCP-B and the corresponding color filters CF1, CF2, and CF3. The low refractive layer LR may be arranged on the light control layer CCL to block or reduce the exposure of the light control patterns CCP-R, CCP-G, and CCP-B to humidity/oxygen. In one or more embodiments, the low refractive layer LR may be arranged between the light control patterns CCP-R, CCP-G and CCP-B and the corresponding color filters CF1, CF2, and CF3 to increase light extraction efficiency or preventing or reducing the incidence of reflective light into the light control layer CCL, thereby playing the role of an optical functional layer. The low refractive layer LR may be a layer having a smaller refractive index compared to adjacent other layers.

The low refractive layer LR may include at least one inorganic layer. For example, in one or more embodiments, the low refractive layer LR may be formed by including one or more selected from among silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride, or a metal thin film securing light transmittance. However, embodiments of the present disclosure are not limited thereto, for example, in some embodiments, the low refractive layer LR may include an organic layer. The low refractive layer LR may have, for example, a structure in which multiple hollow particles are dispersed in an organic polymer resin. The low refractive layer LR may be composed of a single layer or multiple layers.

In one or more embodiments, the light control member CCM may further include a second base substrate BL arranged on the color filter layer CFL. The second base substrate BL may be a member providing a base surface on which the color filter layer CFL, the color control layer CCL, and/or the like are arranged. The second base substrate BL may be a glass substrate, a metal substrate, a plastic substrate, and/or the like. However, embodiments of the present disclosure are not limited thereto, for example, the second base substrate BL may be an inorganic layer, an organic layer, or a composite material layer. In one or more embodiments, the second base substrate BL may not be provided.

FIG. 4B is an enlarged view of a portion of the cross-section of a display device according to one or more embodiments of the present disclosure. FIG. 4B shows a display device DD-1 of one or more embodiments, which is different from the display device DD of one or more embodiments, shown in FIG. 4A.

Referring to FIG. 4B, the display device DD-1 according to one or more embodiments may include a lower panel (e.g., display panel DP) including a first base substrate BS, a circuit element layer DP-CL arranged on the first base substrate BS, and a display element layer DP-LED arranged on the circuit element layer DP-CL, and a light control member CCM-1 arranged on the lower panel. In the display device DD-1 according to one or more embodiments, the light control member CCM-1 may include a light control layer CCL-1, a low refractive layer LR-1, a color filter layer CFL-1, and a second base substrate BL-1, stacked in order (e.g., in the stated order) on a thin film encapsulating layer TFE. The light control member CCM-1 may include a barrier layer CAP1 and an additional barrier layer CAP2, which are respectively arranged on the top and bottom of the light control layer CCL-1.

The light control layer CCL-1 may be arranged on the display element layer DP-LED and the thin film encapsulating layer TFE with the additional barrier layer CAP2 therebetween. The light control layer CCL-1 may include multiple partition wall parts BMP and light control patterns CCP-R, CCP-G, and CCP-B arranged among the partition wall parts BMP. On the light control layer CCL-1, the low refractive layer LR may be arranged.

The light control member CCM-1 may include a base layer providing a base surface on which the light control patterns CCP-R, CCP-G, and CCP-B are formed. The base layer may be arranged adjacent to the light control patterns CCP-R, CCP-G, and CCP-B and may be a layer which is a base of the light control patterns CCP-R, CCP-G, and CCP-B. For example, the additional barrier layer CAP2 may correspond to the base layer on which the light control patterns CCP-R, CCP-G, and CCP-B are provided. However, embodiments of the present disclosure are not limited thereto. If (e.g., when) the additional barrier layer CAP2 is not provided, the thin film encapsulating layer TFE included in the display panel DP may correspond to the base layer on which the light control patterns CCP-R, CCP-G, and CCP-B are provided.

In one or more embodiments, a surface modification layer SM may be arranged on at least one side of the light control patterns CCP-R, CCP-G, and CCP-B. The surface modification layer SM may be arranged between the light control patterns CCP-R, CCP-G, and CCP-B, and the base layer which is the base of the light control patterns CCP-R, CCP-G, and CCP-B. As shown in FIG. 4B, the surface modification layer SM may be arranged between the light control patterns CCP-R, CCP-G, and CCP-B and the additional barrier layer CAP2. The surface modification layer SM may make contact with the one side of the light control patterns CCP-R, CCP-G, and CCP—B adjacent to the display panel DP. The bottom of the surface modification layer SM may make contact with the top of the additional barrier layer CAP2 exposed by a partition wall opening part BW-OH, and the top of the surface modification layer SM may make contact with the bottom of the light control patterns CCP-R, CCP-G, and CCP-B.

In one or more embodiments, the surface modification layer SM may be arranged in the partition wall opening part BW-OH. The partition wall part BMP may include a first side adjacent to the first base substrate BS, a second side oppositely arranged to the first side, and a third side connecting the first side and the second side. The third side may correspond to the inner side portion of the partition wall part BMP. The surface modification layer SM may be arranged on the bottom of the additional barrier layer CAP2 exposed by the partition wall opening part BW-OH. The surface modification layer SM may make contact with the bottom of the additional barrier layer CAP2 exposed by the partition wall opening part BW-OH. In one or more embodiments, at least a portion of the surface modification layer SM may be arranged on the third side corresponding to the inner side portion of the partition wall part BMP and the second side corresponding to the top of the partition wall part BMP. For example, as shown in FIG. 4B, a surface modification layer SM may be arranged on the bottom of the additional barrier layer CAP2 exposed by the partition wall opening part BW-OH, and on the second side and the third side of the partition wall part BMP.

The color filter layer CFL-1 may include multiple color filters CF1, CF2, and CF3, and a light blocking part BM.

Compared to the display device DD shown in FIG. 4A, the display device DD-1 according to one or more embodiments, shown in FIG. 4B, is an embodiment in which the light control layer CCL-1, the low refractive layer LR and the color filter layer CFL-1 are arranged with the top of the thin film encapsulating layer TFE as a base surface. For example, the light control patterns CCP-R, CCP-G, and CCP-B of the light control layer CCL-1 may be formed on the thin film encapsulating layer TFE by a substantially continuous process, and the color filters CF1, CF2, and CF3 of the color filter layer CFL-1 may be formed in order on the light control layer CCL-1 by a substantially continuous process. The light control layer CCL-1 may be formed with the top of the additional barrier layer CAP2 arranged on the thin film encapsulating layer TFE as a base surface, and may have a shape that is inverted upside down in contrast to the shape of the light control layer CCL shown in FIG. 4A. For example, multiple partition wall parts BMP and multiple light control patterns CCP-R, CCP-G, and CCP-B may have shapes that are inverted upside down in contrast to the shape shown in FIG. 4A. The color filter layer CFL-1 may be formed with the top of the light control layer CCL-1 as a base surface and may have a different shape from that shown in FIG. 4A.

In the color filter layer CFL-1 of one or more embodiments, the light blocking part BM may be a black matrix. The light blocking part BM may be formed by including an organic light blocking material and/or an inorganic light blocking material, including a black pigment and/or a black dye. The light blocking part BM may prevent or reduce light leakage phenomenon and separate the boundary among adjacent color filters CF3, CF2, and CF1.

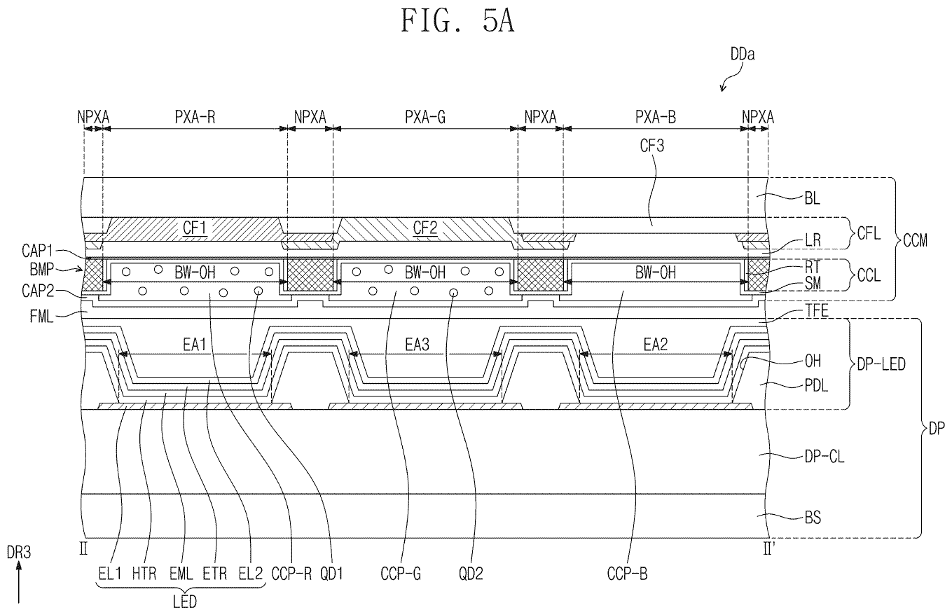

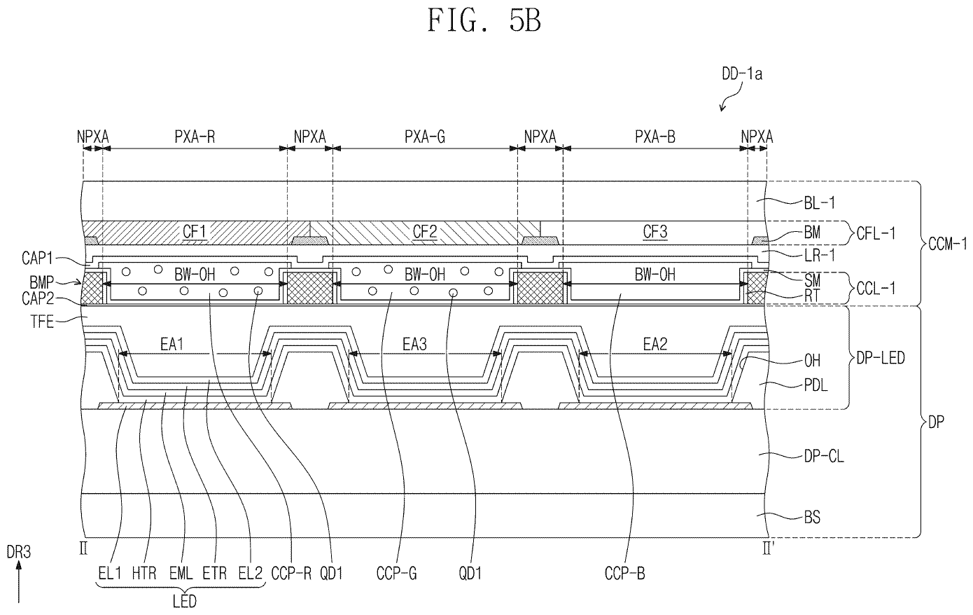

FIG. 5A and FIG. 5B each show an enlarged view of a partial region in the cross-sections of a display device according to one or more embodiments of the present disclosure. FIG. 5A and FIG. 5B respectively show display devices DDa and DD-1a according to one or more embodiments, which are different from the display devices DD and DD-1 of embodiments, shown in FIG. 4A and FIG. 4B.

Referring to FIG. 5A and FIG. 5B, the display devices DDa and DD-1a according to one or more embodiments may further include a reflection pattern RT, compared to the display devices DD and DD-1, respectively shown in FIG. 4A and FIG. 4B.

Referring to FIG. 5A and FIG. 5B, in one or more embodiments, in the display devices DDa and DD-1a, light control members CCM and CCM-1 may each include a reflection pattern RT arranged on the inner side portion of the partition wall part BMP. The reflection pattern RT may include a metal. The reflection pattern RT may include a metal having a relatively high reflectivity, for example, aluminum. The reflection pattern RT may be provided on the inner side portion of the partition wall part BMP and may be separately arranged from the light control patterns CCP-R, CCP-G, and CCP-B with a surface modification layer SM therebetween.

The reflection pattern RT may cover the entire inner side portion of the partition wall part BMP. As a result, the inner side portion of the partition wall part BMP may not be exposed by the reflection pattern RT. Because the reflection pattern RT is arranged on the inner side portion of the partition wall part BMP, source light emitted from a display element layer DP-LED may be recirculated via the reflection pattern RT, and the efficiency of light emitting outside via the partition wall opening part BW-OH may be improved.

The surface modification layer SM may be arranged between the reflection pattern RT and the light control patterns CCP-R, CCP-G, and CCP-B and may improve the bonding force between the reflection pattern RT and the light control patterns CCP-R, CCP-G, and CCP-B.

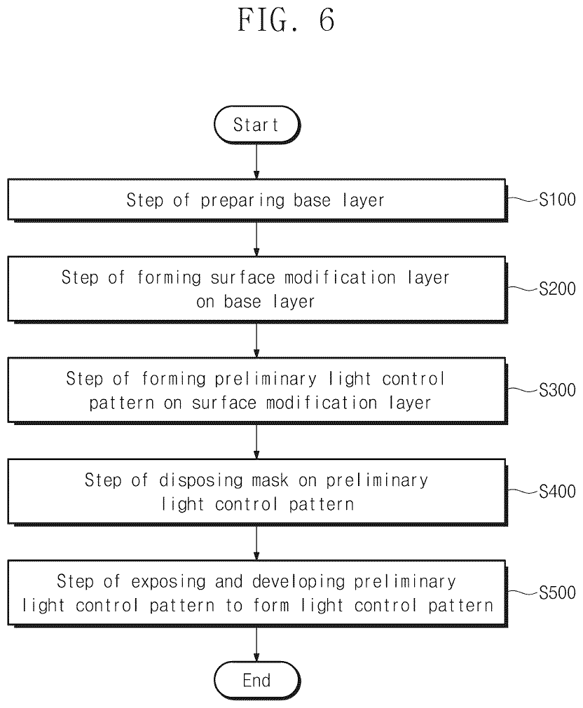

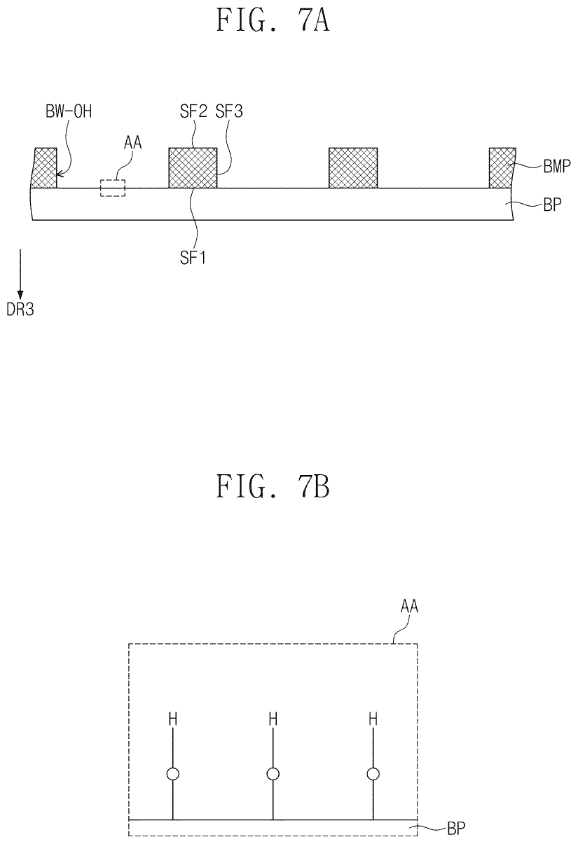

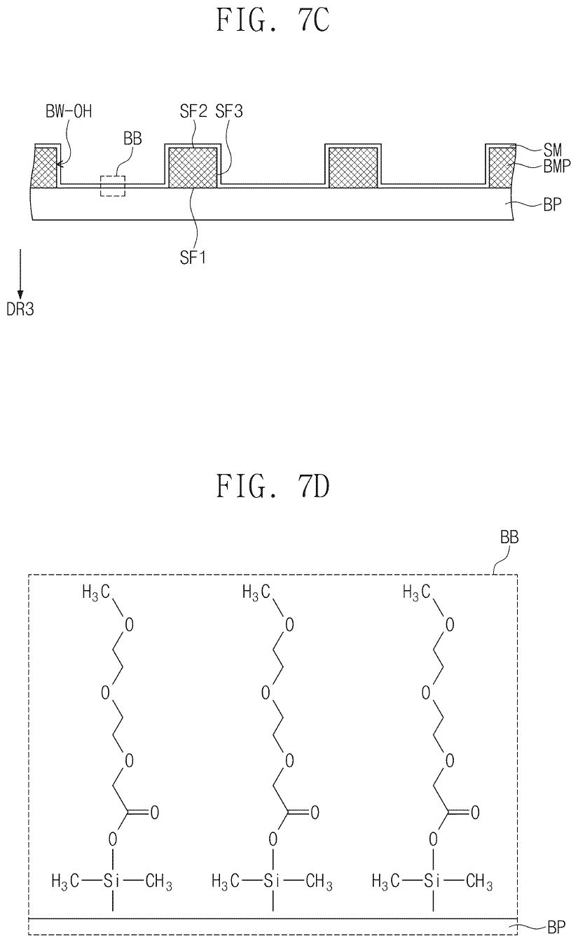

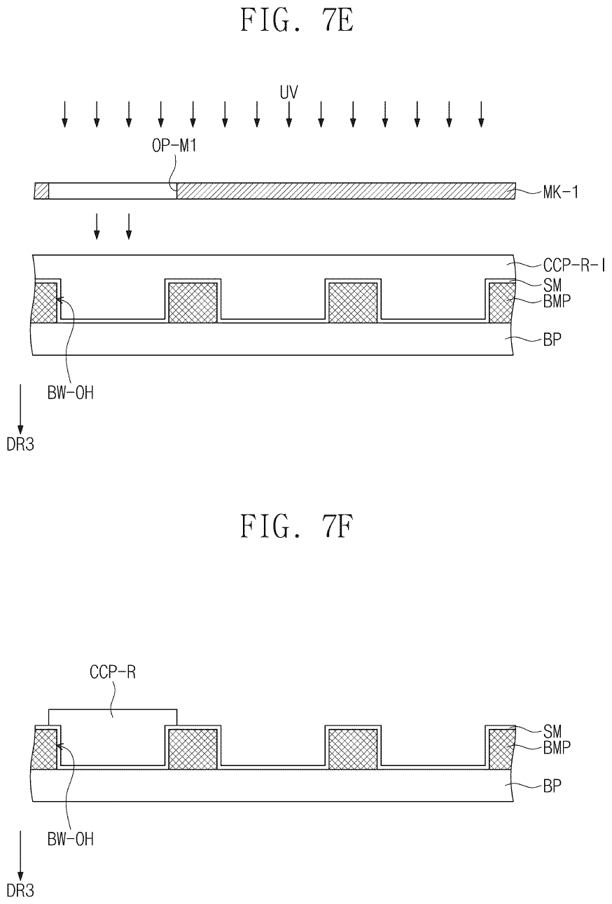

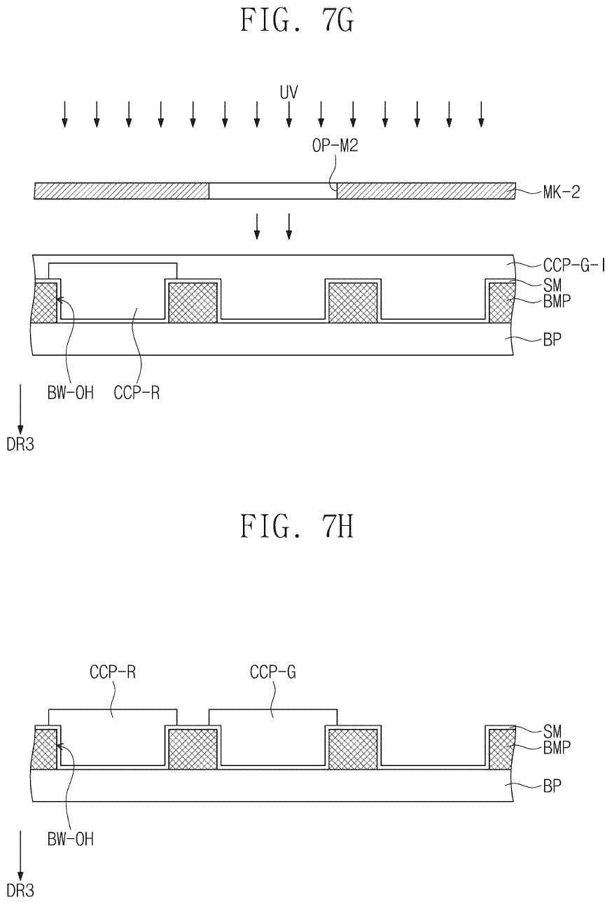

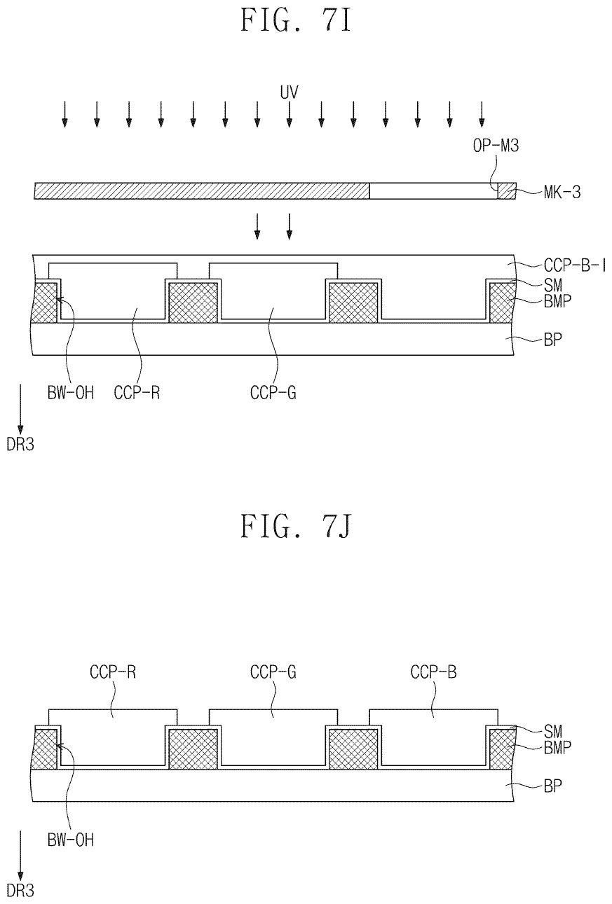

FIG. 6 is a flowchart showing a method of manufacturing a display device according to one or more embodiments of the present disclosure. FIG. 7A to FIG. 7J are each a diagram showing some steps (e.g., operations or acts) of a method of manufacturing a display device according to one or more embodiments of the present disclosure. In FIG. 7A to FIG. 7J, the steps/operations for forming (or providing) a light control part (e.g., light control patterns) is shown in order in the method of manufacturing a display device according to one or more embodiments of the present disclosure. FIG. 7B is an enlarged cross-sectional view showing a portion corresponding to area “AA” in FIG. 7A. FIG. 7D is an enlarged cross-sectional view showing a portion corresponding to area “BB” in FIG. 7C. Hereinafter, in explaining the method of manufacturing a display device according to one or more embodiments with reference to FIG. 7A to FIG. 7J, the same reference symbols are given for the same configurations as the configurations explained above, and detailed explanation thereon will not be provided for conciseness.

The method of manufacturing a display device according to one or more embodiments of the present disclosure may include a step (e.g., an operation or act) of preparing a display panel and a step (e.g., an operation or act) of forming (or providing) a light control part (e.g., light control patterns)) on the display panel.

Referring to FIG. 6, the method of manufacturing a display device according to one or more embodiments includes a step (e.g., an operation or act) of preparing a base layer (S100), a step (e.g., an operation or act) of forming (or providing) a surface modification layer on the base layer (S200), a step (e.g., an operation or act) of forming (or providing) a preliminary light control pattern on the surface modification layer (S300), a step (e.g., an operation or act) of disposing a mask on the preliminary light control pattern (S400), and a step (e.g., an operation or act) of exposing and developing the preliminary light control pattern to form (or provide) a light control pattern (S500).

The method of manufacturing a display device according to one or more embodiments of the present disclosure may include a step (e.g., an operation or act) of preparing a base layer (S100). A base layer BP may provide a base surface for forming (or providing) a partition wall part BMP and light control patterns CCP-R, CCP-G, and CCP-B. The base layer BP may include a functional layer including the light control member CCM shown in FIG. 4A, and the partition wall part BMP and the light control patterns CCP-R, CCP-G, and CCP-B may be formed on a base surface provided by a functional layer included in the light control member CCM, for example, a barrier layer CAP1. However, embodiments of the present disclosure are not limited thereto, and the base layer BP may include the display panel DP shown in FIG. 4B and/or the like, and the partition wall part BMP and the light control patterns CCP-R, CCP-G, and CCP-B may be formed on a base surface provided by the functional layer included in the display panel DP, for example, the first base substrate BS, the circuit element layer DP-CL, the display element layer DP-LED, and/or the like. For example, in one or more embodiments, the base layer BP may include the functional layer included in the display panel DP shown in FIG. 4B, and the partition wall part BMP and the light control patterns CCP-R, CCP-G, and CCP-B may be formed on a base surface provided by a functional layer included in the display panel DP, for example, the thin film encapsulating layer TFE. In one or more embodiments, if (e.g., when) the light control member CCM further includes an additional barrier layer CAP2, after forming (or providing) the additional barrier layer CAP2 on the thin film encapsulating layer TFE, the partition wall part BMP and the light control patterns CCP-R, CCP-G, and CCP-B may be formed on a base surface provided by the additional barrier layer CAP2.

Referring to FIG. 7A, the method of manufacturing a display device according to one or more embodiments may further include a step (e.g., an operation or act) of forming (or providing) a partition wall part BMP on a base layer BP prior to the step/operation of forming (or providing) a surface modification layer SM. On one side of the base layer BP, the partition wall part BMP may be formed. In the base layer BP, multiple pixel areas may be defined. The multiple pixel areas defined in the base layer BP may correspond to the first to third pixel areas PXA-R, PXA-G, and PXA-B, explained in FIG. 3 and/or the like. In the step/operation of forming (or providing) the partition wall part BMP, partition wall opening parts BW-OH corresponding to the multiple pixel areas PXA-R, PXA-G, and PXA-B may be formed.

The partition wall part BMP may include a first side SF1 adjacent to the base layer BP, a second side SF2 oppositely arranged to the first side SF1 and separated from the base layer BP, and a third side SF3 connecting the first side SF1 and the second side SF2. The third side SF3 may correspond to the inner side portion of the partition wall part BMP.

Referring to FIG. 7A to FIG. 7D, the step/operation of forming (or providing) a light control part (e.g., light control patterns) in the method of manufacturing a display device according to one or more embodiments, may include a step (e.g., an operation or act) of forming (or providing) a surface modification layer SM including a first compound (e.g., a first chemical moiety) on the base layer BP. The surface modification layer SM may be provided on one side of the base layer BP. The surface modification layer SM may include the first compound (e.g., the first chemical moiety). The same contents explained in FIG. 4A and/or the like may be applied for the first compound (e.g., the first chemical moiety).

In one or more embodiments, the method of manufacturing a display device according to one or more embodiments may further include a step (e.g., an operation or act) of pre-treating the surface of the base layer BP prior to the step/operation of forming (or providing) the surface modification layer SM. The step/operation of pre-treating the surface of the base layer BP may be performed to increase the reactivity between a composition for forming (or providing) the surface modification layer SM and the base layer BP. The pre-treating step/operation may be performed by oxidizing a portion of the surface of the base layer BP prior to forming (or providing) the surface modification layer SM on the base layer BP.

In one or more embodiments, the pre-treating step/operation may include treating the surface of the base layer BP with ultraviolet or oxygen and/or ozone plasma. As shown in FIG. 7B, on the surface of the pre-treated base layer BP, hydroxyl groups (—OH) may be formed. The hydroxyl groups (—OH) formed on the surface of the base layer BP may play the role of increasing the reactivity with a preliminary coupling agent included in a composition for forming (or providing) the surface modification layer SM, which will be explained later. Accordingly, the adhesiveness between the base layer BP and the surface modification layer SM may be improved. However, embodiments of the present disclosure are not limited thereto, for example, the pre-treating step/operation may not be provided according to the physical properties of the base layer BP. For example, if the surface of the base layer BP has a reacting group which is capable of performing sufficient reaction with the preliminary coupling agent, the pre-treating step/operation may not be provided.

Referring to FIG. 7C and FIG. 7D, the step/operation of forming (or providing) the surface modification layer SM may further include a step (e.g., an operation or act) of providing a preliminary coupling agent onto the base layer BP and a step (e.g., an operation or act) of reacting the preliminary coupling agent with the hydroxyl group (—OH) formed at the surface of the base layer BP. The preliminary coupling agent may be a compound having a functional group which may interact with the surface of the base layer BP. The functional group may refer to a group which is capable of forming (or providing) a bond including a covalent bond, a hydrogen bond, or a chemical adsorption with the surface of the base layer BP. The surface modification layer SM may be formed by providing the preliminary coupling agent to the base layer BP for the reaction of the preliminary coupling agent with the surface of the base layer BP. The step/operation of providing the preliminary coupling agent to the base layer BP may be performed by preparing a surface modification composition including the preliminary coupling agent and applying the composition onto the base layer BP. The surface modification composition may include water as a catalyst, but embodiments of the present disclosure are not limited thereto.

In one or more embodiments, the preliminary coupling agent may be represented by Formula 1-1 or Formula 1-2.

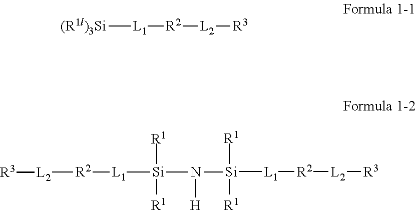

In Formula 1-1, R¹¹ may be a halogen, a hydroxyl group, a substituted or unsubstituted alkoxy group of 1 to 20 carbon atoms, or a substituted or unsubstituted alkyl group of 1 to 20 carbon atoms. At least one selected from among multiple R¹¹ may be a halogen, a hydroxyl group, or a substituted or unsubstituted alkoxy group of 1 to 20 carbon atoms. For example, in one or more embodiments, at least one selected from among multiple R¹¹ may be a functional group which may play the role of a leaving group in a nucleophilic substitution reaction which will be explained later.

In Formula 1-1 and Formula 1-2, the same contents explained in Formula 1 may be applied for R¹ to R³, L₁, and L₂.

In one or more embodiments, the preliminary coupling agent may be represented by Formula 1-1a or Formula 1-2a.

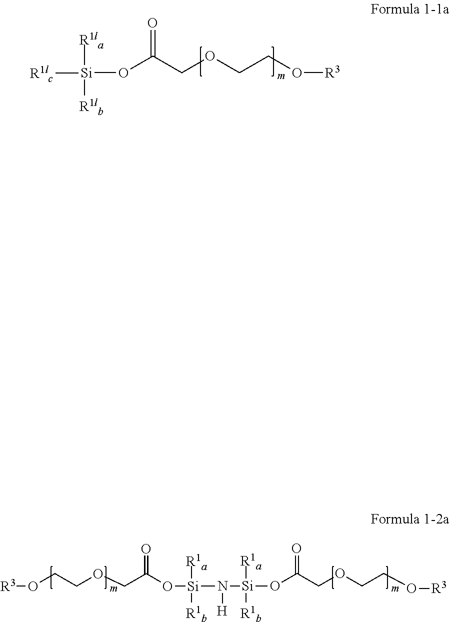

In Formula 1-1a, R¹¹ₐ to R¹¹_{c} may each independently be a halogen, a hydroxyl group, a substituted or unsubstituted alkoxy group of 1 to 20 carbon atoms, or a substituted or unsubstituted alkyl group of 1 to 20 carbon atoms. In Formula 1-1, at least one selected from among R¹¹ₐ to R¹¹, may be a halogen, a hydroxyl group, or a substituted or unsubstituted alkoxy group of 1 to 20 carbon atoms. For example, in one or more embodiments, at least one selected from among R¹¹ₐ to R¹¹_{c} may be a functional group which may play the role of a leaving group in a nucleophilic substitution reaction which will be explained later.

In Formula 1-1a and Formula 1-2a, the same contents explained in Formula 2 may be applied for R¹ₐ, R¹_{b}, R², R³, and “m”.

The formation of the surface modification layer SM on the base layer may be represented by Reaction 1. In Reaction 1, an embodiment in which the compound represented by Formula 1-2a is utilized as the preliminary coupling agent in the step/operation of forming (or providing) the surface modification layer SM is shown as an example, but embodiments of the present disclosure are not limited thereto.

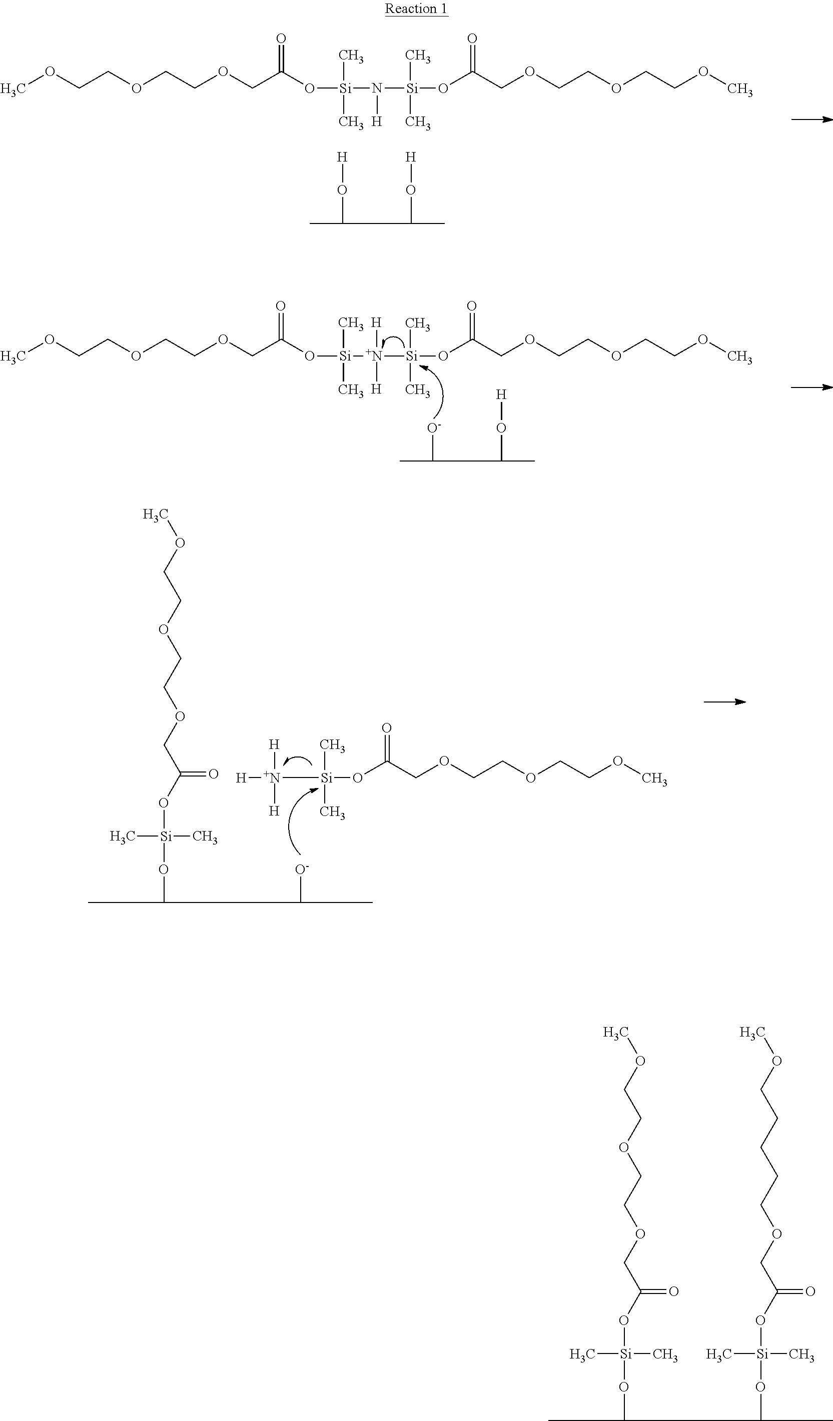

Referring to Reaction 1, a thin film composed of the hydroxyl groups (—OH) may be present on the surface of the base layer BP, and the preliminary coupling agent may be provided on the film to be physically adsorbed. As shown in Reaction 1, the oxygen of the hydroxyl (—OH) functional group formed on the surface of the base layer BP and the preliminary coupling agent may undergo a nucleophilic substitution reaction, and ammonia (NH₃) may be eliminated as a gas to form (or provide) the bond between the base layer BP and the coupling agent.

Referring to FIG. 7C again, the surface modification layer SM may be arranged on one side of the base layer BP exposed by multiple partition wall opening parts BW-OH defined in the partition wall part BMP. In one or more embodiments, at least a portion of the surface modification layer SM may be arranged on the second side SF2 and the third side SF3 of the partition wall part BMP.

In one or more embodiments, the method of manufacturing a display device of one or more embodiments may further include a step (e.g., an operation or act) of washing the base layer BP after the step/operation of forming (or providing) the surface modification layer SM. After forming (or providing) the surface modification layer SM on the base layer BP, the base layer BP may be washed utilizing a washing solution such as de-ionized water or pure water. By the washing process, the preliminary coupling agent unreacted with the surface of the base layer BP and impurities may be removed. However, embodiments of the present disclosure are not limited thereto, for example, the step/operation of washing the base layer BP may not be provided according to process conditions.

Referring to FIG. 7E to FIG. 7J, a step (e.g., an operation or act) of forming (or providing) light control patterns CCP-R, CCP-G, and CCP-B may be performed after the step/operation of forming (or providing) the surface modification layer SM. In the display devices DD, DD-1, DDa, and DD-1a, explained in FIG. 3 to FIG. 5B, at least one selected from among the multiple light control patterns CCP-R, CCP-G, and CCP-B included in the light control layers CCL and CCL-1 may be formed through the step/operation of forming (or providing) the light control patterns CCP-R, CCP-G, and CCP-B of one or more embodiments, which will be explained later. For example, at least one selected from among multiple light control patterns CCP-R, CCP-G, and CCP-B may be formed through a photolithography process. In FIG. 7E to FIG. 7J, the formation of all the first to third light control patterns CCP-R, CCP-G, and CCP-B by the photolithography process is shown as an example, but embodiments of the present disclosure are not limited thereto.

The method of manufacturing a display device according to one or more embodiments may include a step (e.g., an operation or act) of forming (or providing) preliminary light control patterns CCP—R-I, CCP-G-I, and CCP-B-I, and a step (e.g., an operation or act) of patterning the preliminary light control patterns CCP—R-I, CCP-G-I, and CCP-B-I.

Masks MK-1, MK-2, and MK-3 may include areas having different light transmittance in the masks MK-1, MK-2, and MK-3. The masks MK-1, MK-2, and MK-3 may each include a transmission part and a light blocking part. The transmission part of each of the masks MK-1, MK-2, and MK-3 may be an area transmitting light irradiated onto the respective masks MK-1, MK-2, and MK-3. The light blocking part of each of the masks MK-1, MK-2, and MK-3 may be an area blocking light irradiated onto the respective masks MK-1, MK-2, and MK-3. In the masks MK-1, MK-2 and MK-3, the positions of their corresponding transmission part and corresponding light blocking part may be changed according to the pattern to be formed from the preliminary light control patterns CCP—R-I, CCP-G-I, and CCP-B-I utilizing the masks MK-1, MK-2 and MK-3. The preliminary light control patterns CCP—R-I, CCP-G-I, and CCP-B-I may be cured by light provided onto the masks MK-1, MK-2, and MK-3. Light transmitted through the masks MK-1, MK-2, and MK-3 may be provided onto the preliminary light control patterns CCP—R-I, CCP-G-I, and CCP-B-I, and the preliminary light control patterns CCP—R-I, CCP-G-I, and CCP-B-I may be cured according to the pattern of the masks MK-1, MK-2, and MK-3 to show the shape of patterned light control patterns CCP-R, CCP-G, and CCP-B. In one or more embodiments, the light irradiated onto the masks MK-1, MK-2, and MK-3 may be ultraviolet light (UV). The ultraviolet light (UV) may be provided utilizing a projection type or kind stepper.

Referring to FIG. 7E and FIG. 7F, the first light control pattern CCP-R may be formed on the base layer BP and the partition wall part BMP.

Referring to FIG. 7E, a first preliminary light control pattern CCP—R-I may be formed on the base layer BP and the partition wall part BMP. The first preliminary light control pattern CCP—R-I may be formed on the surface modification layer SM. The first preliminary light control pattern CCP—R-I may be formed by applying a first photoresist composition including a first quantum dot QD1 (FIG. 4A and FIG. 4B) on the surface modification layer SM. The first photoresist composition may include a photosensitive material. The physical properties of the first preliminary light control pattern CCP—R-I formed utilizing the first photoresist composition including the photosensitive material may be changed according to the irradiation or not of light.

The first preliminary light control pattern CCP—R-I may be formed to overlap with multiple pixel areas PXA-R, PXA-G, and PXA-B (FIG. 4A and FIG. 4B) and a peripheral area NPXA (FIG. 4A and FIG. 4B) adjacent to the multiple pixel areas PXA-R, PXA-G, and PXA-B. The first preliminary light control pattern CCP—R-I may be formed in a partition wall opening part BW-OH corresponding to at least the first pixel area PXA-R (FIG. 4A and FIG. 4B). The first photoresist composition for forming (or providing) the first preliminary light control pattern CCP—R-I may be provided in the partition wall opening part BW-OH corresponding to at least the first pixel area PXA-R (FIG. 4A and FIG. 4B). The first preliminary light control pattern CCP—R-I may be provided to have a constant thickness on the partition wall part BMP. For example, in one or more embodiments, a distance from the top surface of the base layer BP to the first preliminary light control pattern CCP—R-I may be constant in the multiple pixel areas PXA-R, PXA-G, and PXA-B (FIG. 4A and FIG. 4B) and the peripheral area NPXA (FIG. 4A and FIG. 4B).

After that, a step (e.g., an operation or act) of patterning the first preliminary light control pattern CCP—R-I to form (or provide) a first light control pattern CCP-R may be performed. As shown in FIG. 7E and FIG. 7F, the first preliminary light control pattern CCP—R-I may be patterned utilizing a photolithography process. In order to pattern the first preliminary light control pattern CCP—R-I, a first mask MK-1 may be arranged on the first preliminary light control pattern CCP—R-I. In the first mask MK-1, a first mask opening part OP-M1 corresponding to the first pixel area PXA-R (FIG. 4A and FIG. 4B) may be defined. The first mask opening part OP-M1 defined in the first mask MK-1 may correspond to the above-described transmission part. Light (UV) transmitted through the first mask opening part OP-M1 of the first mask MK-1 may be provided onto the first preliminary light control pattern CCP—R-I. In the first preliminary light control pattern CCP—R-I, a portion provided with the light (UV) transmitted through the first mask opening part OP-M1 may be cured.

Then, if (e.g., when) the first preliminary light control pattern CCP—R-I exposed through the first mask MK-1 is developed, the portion provided with the light (UV) transmitted through the first mask opening part OP-M1 in the first preliminary light control pattern CCP—R-I may not be removed but remain, as shown in FIG. 7F. An overlapping portion with the first mask opening part OP-M1 in the first preliminary light control pattern CCP—R-I may form (or provide) the first light control pattern CCP-R, shown in FIG. 7F. A non-overlapping portion with the first mask opening part OP-M1 in the first preliminary light control pattern CCP—R-I may be blocked from light (UV). After developing the first preliminary light control pattern CCP—R-I exposed through the first mask MK-1, the portion where the light (UV) is not provided may be completely removed from the first preliminary light control pattern CCP—R-I.

Referring to FIG. 7G and FIG. 7H, a second light control pattern CCP-G may be formed on the base layer BP and the partition wall part BMP.

Referring to FIG. 7G, a second preliminary light control pattern CCP-G-I may be formed on the base layer BP and the partition wall part BMP. The second preliminary light control pattern CCP-G-I may be formed on the surface modification layer SM. The second preliminary light control pattern CCP-G-I may be formed by applying a second photoresist composition including a second quantum dot QD2 (see FIG. 4A and FIG. 4B) on the surface modification layer SM. The second photoresist composition may include a photosensitive material. The physical properties of the second preliminary light control pattern CCP-G-I formed utilizing the second photoresist composition including the photosensitive material may be changed according to the irradiation or not of light.

The second preliminary light control pattern CCP-G-I may be formed to overlap with multiple pixel areas PXA-R, PXA-G and PXA-B (FIG. 4A and FIG. 4B) and a peripheral area NPXA (FIG. 4A and FIG. 4B). The second preliminary light control pattern CCP-G-I may be arranged in a partition wall opening part BW-OH corresponding to at least the second pixel area PXA-G (FIG. 4A and FIG. 4B). The second photoresist composition for forming (or providing) the second preliminary light control pattern CCP-G-I may be provided in the partition wall opening part BW-OH corresponding to at least the second pixel area PXA-G (FIG. 4A and FIG. 4B). The second preliminary light control pattern CCP-G-I may be provided to have a constant thickness on the partition wall part BMP. For example, in one or more embodiments, a distance from the top of the base layer BP to the top of the second preliminary light control pattern CCP-G-I may be constant in the multiple pixel areas PXA-R, PXA-G, and PXA-B (FIG. 4A and FIG. 4B) and the peripheral area NPXA (FIG. 4A and FIG. 4B).

After that, a step (e.g., an operation or act) of patterning the second preliminary light control pattern CCP-G-I to form (or provide) a second light control pattern CCP-G may be performed. As shown in FIG. 7G and FIG. 7H, the second preliminary light control pattern CCP-G-I may be patterned utilizing a photolithography process. In order to pattern the second preliminary light control pattern CCP-G-I, a second mask MK-2 may be arranged on the second preliminary light control pattern CCP-G-I. In the second mask MK-2, a second mask opening part OP-M2 corresponding to the second pixel area PXA-G (FIG. 4A and FIG. 4B) may be defined. Light (UV) transmitted through the second mask opening part OP-M2 of the second mask MK-2 may be provided to the second preliminary light control pattern CCP-G-I. In the second preliminary light control pattern CCP-G-I, a portion provided with the light (UV) transmitted through the second mask opening part OP-M2 may be cured.

Then, if (e.g., when) the second preliminary light control pattern CCP-G-I exposed through the second mask MK-2 is developed, the portion provided with the light (UV) transmitted through the second mask opening part OP-M2 in the second preliminary light control pattern CCP-G-I may not be removed but remain, as shown in FIG. 7H. An overlapping portion with the second mask opening part OP-M2 in the second preliminary light control pattern CCP-G-I may form (or provide) the second light control pattern CCP-G, shown in FIG. 7H. A non-overlapping portion with the second mask opening part OP-M2 in the second preliminary light control pattern CCP-G-I may be blocked from light (UV). After developing the second preliminary light control pattern CCP-G-I exposed through the second mask MK-2, the portion where the light (UV) is not provided may be completely removed from the second preliminary light control pattern CCP-G-I.

Referring to FIG. 7I and FIG. 7J, a third light control pattern CCP-B may be formed on the base layer BP and the partition wall part BMP.

Referring to FIG. 7I, a third preliminary light control pattern CCP-B-I may be formed on the base layer BP and the partition wall part BMP. The third preliminary light control pattern CCP-B-I may be formed on the surface modification layer SM. The third preliminary light control pattern CCP-B-I may be formed by applying a third photoresist composition on the surface modification layer SM. However, embodiments of the present disclosure are not limited thereto, for example, in some embodiments, the third photoresist composition may include a quantum dot. The third photoresist composition may include a photosensitive material. The physical properties of the third preliminary light control pattern CCP-B-I formed utilizing the third photoresist composition including the photosensitive material may be changed according to the irradiation or not of light. In one or more embodiments, the third photoresist composition may not include (e.g., may exclude) a quantum dot, different from the first and second photoresist compositions. The third photoresist composition may include a base resin and a dispersant dispersed in the base resin. However, embodiments of the present disclosure are not limited thereto, for example, in some embodiments, the third photoresist composition may further include a third quantum dot.

The third preliminary light control pattern CCP-B-I may be formed to overlap with multiple pixel areas PXA-R, PXA-G, and PXA-B (FIG. 4A and FIG. 4B) and a peripheral area NPXA (FIG. 4A and FIG. 4B). The third preliminary light control pattern CCP-B-I may be arranged in a partition wall opening part BW-OH corresponding to at least the third pixel area PXA-B (FIG. 4A and FIG. 4B). The third photoresist composition for forming (or providing) the third preliminary light control pattern CCP-B-I may be provided in the partition wall opening part BW-OH corresponding to at least the third pixel area PXA-B (FIG. 4A and FIG. 4B). The third preliminary light control pattern CCP-B-I may be provided to have a constant thickness on the partition wall part BMP. For example, in one or more embodiments, a distance from the top of the base layer BP to the top of the third preliminary light control pattern CCP-B-I may be constant in the multiple pixel areas PXA-R, PXA-G, and PXA-B (FIG. 4A and FIG. 4B) and the peripheral area NPXA (FIG. 4A and FIG. 4B).

After that, a step (e.g., an operation or act) of patterning the third preliminary light control pattern CCP-B-I to form (or provide) a third light control pattern CCP-B may be performed. As shown in FIG. 7I and FIG. 7J, the third preliminary light control pattern CCP-B-I may be patterned utilizing a photolithography process. In order to pattern the third preliminary light control pattern CCP-B-I, a third mask MK-3 may be arranged on the third preliminary light control pattern CCP-B-I. In the third mask MK-3, a third mask opening part OP-M3 corresponding to the third pixel area PXA-B (FIG. 4A and FIG. 4B) may be defined. Light (UV) transmitted through the third mask opening part OP-M3 of the third mask MK-3 may be provided onto the third preliminary light control pattern CCP-B-I. In the third preliminary light control pattern CCP-B-I, a portion provided with the light (UV) transmitted through the third mask opening part OP-M3 may be cured.

Then, if (e.g., when) the third preliminary light control pattern CCP-B-I exposed through the third mask MK-3 is developed, the portion provided with the light (UV) transmitted through the third mask opening part OP-M3 in the third preliminary light control pattern CCP-B-I may not be removed but remain, as shown in FIG. 7J. An overlapping portion with the third mask opening part OP-M3 in the third preliminary light control pattern CCP-B-I may form (or provide) the third light control pattern CCP-B, shown in FIG. 7J. A non-overlapping portion with the third mask opening part OP-M3 in the third preliminary light control pattern CCP-B-I may be blocked from light (UV). After developing the third preliminary light control pattern CCP-B-I through the third mask MK-3, the portion where the light (UV) is not provided may be completely removed from the third preliminary light control pattern CCP-B-I.

In one or more embodiments, in the explanation on FIG. 7E to FIG. 7J, an embodiment utilizing a negative photosensitive solution by which an unexposed portion of a preliminary light control pattern is removed, is explained as an example, but embodiments of the present disclosure are not limited thereto, for example, in one or more embodiments, a positive photosensitive solution by which an exposed portion of a photosensitive layer is removed may be utilized.

Hereinafter, the light control pattern according to one or more embodiments of the present disclosure will be explained in particular referring to one or more embodiments and comparative embodiments. The embodiments shown are examples to assist the understanding of the present disclosure, and the scope of the present disclosure is not limited thereto.

### EXAMPLES

### 1. Manufacture of Light Control Pattern

### Example 1

On a base layer with a partition wall part in which an opening part was defined was formed, a preliminary coupling agent represented by Example Compound 1 (see the structure listed in Table 1) was sprayed and then heat-treated at about 90° C. for about 60 seconds to form (or provide) a surface modification layer. The base layer utilized a substrate including SiONₓ. Then, a photoresist composition including a quantum dot was applied by spin coating on the base layer to form (or provide) a photoresist layer. In Example 1, a quantum dot having an InP/ZnSe/ZnS core-shell structure and a 4,7,10,13, 16-pentaoxaheptadecanoic acid (mPEG4—OCH₂CH₂COOH) ligand was bonded to the surface thereof was utilized. In addition, the quantum dot content (e.g., amount) included in the photoresist composition was about 50 wt % on the bases of the total amount of the photoresist composition. The photoresist layer thus obtained was pre-baked at about 80° C. for about 150 seconds. The pre-baked layer was exposed to ultraviolet utilizing a stepper, and then, developed utilizing KOH at about 25° C. for about 2 minutes to form (or provide) a pattern. The pattern thus formed was hard baked in an oven at about 180° C. for about 30 minutes to form (or provide) a light control pattern.

### Example 2

Example 2 was formed by the same method as Example 1 except for changing the content (e.g., amount) of the quantum dot included in the photoresist composition to about 70 wt %.

### 1 Comparative Example 1

Comparative Example 1 was formed by the same method as Example 1 except for omitting the step/operation of forming (or providing) the surface modification layer and changing the content (e.g., amount) of the quantum dot included in the photoresist composition to about 43 wt %.

### Comparative Example 2

Comparative Example 2 was formed by the same method as Example 1 except for omitting the step/operation of forming (or providing) the surface modification layer and changing the content (e.g., amount) of the quantum dot included in the photoresist composition to about 50 wt %.

### Comparative Example 3

Comparative Example 3 was formed by the same method as Example 1 except for utilizing Comparative Compound 1 (see the structure listed in Table 1) instead of Example Compound 1 during forming (or providing) the surface modification layer.

### Comparative Example 4

Comparative Example 4 was formed by the same method as Example 2 except for utilizing Comparative Compound 1 instead of Example Compound 1 during forming (or providing) the surface modification layer.

### Comparative Example 5

Comparative Example 5 was formed by the same method as Example 2 except for utilizing Comparative Compound 2 (see the structure listed in Table 1) instead of Example Compound 1 during forming (or providing) the surface modification layer.

### Comparative Example 6

Comparative Example 6 was formed by the same method as Example 2 except for utilizing Comparative Compound 3 (see the structure listed in Table 1) instead of Example Compound 1 during forming (or providing) the surface modification layer.

The types (kinds) of the preliminary coupling agents and the contents of the quantum dot for Example 1, Example 2, and Comparative Examples 1 to 6 are shown in Table 1.

TABLE 1

| | | Quantum |
|---|---|---|
| | | dot |
| | | content |
| | | (e.g., |
| | | amount) |
| Division | Coupling agent | (%) |
| Example 1 | 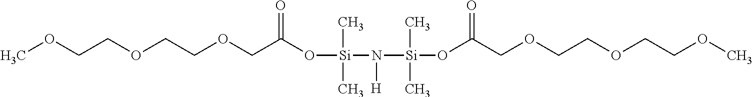 Example Compound 1 | 50 |
| Example 2 | 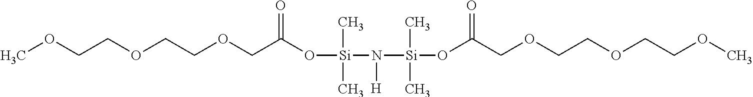 Example Compound 1 | 70 |
| Comparative | — | 43 |
| Example | | |
| 1 | | |
| Comparative | — | 50 |
| Example | | |
| 2 | | |
| Comparative Example 3 | 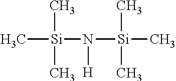 Comparative Compound 1 | 50 |
| Comparative Example 4 | 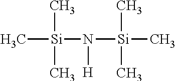 Comparative Compound 1 | 70 |
| Comparative Example 5 | 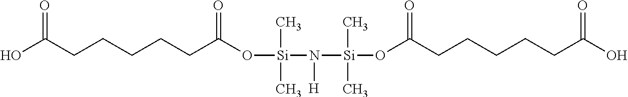 [SMILES: C[Si](C)(N[Si](C)(C)OC(=O)CCCCCC(=O)O)OC(=O)CCCCCC(=O)O] Comparative Compound 2 | 70 |
| Comparative Example 6 | 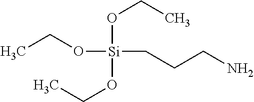 Comparative Compound 3 | 70 |

### 2. Evaluation of Light Control Pattern

In Table 2, the power conversion efficiency (PCE), the power conversion efficiency retention ratio, and the layer state of each of the Examples and Comparative Examples were evaluated, and the results are shown. In Table 2, the measurement of the power conversion efficiency of each of the Examples and Comparative Examples was conducted utilizing a QE-2000 (Otsuka Co.) equipment, by obtaining a reference first by putting a bare glass on a blue BLU (456 nm) covered with a diffusing film and measuring utilizing a detector, and then, calculating the area of the emission peak of converted light with respect to the area of the absorption peak of blue light. For example, the power conversion efficiency (PCE) of each of the Examples and Comparative Examples was calculated by Equation 1.

PCE=(A₂/A₁)×100 Equation 1

In Equation 1, A₁ refers to the area of the absorption spectrum of blue light, and A₂ refers to the area of emission spectrum on converted light. For example, A₁ may correspond to the area of the absorption peak on blue light absorbed by the quantum dot. A₂ may correspond to the area of the emission peak on the light converted by the quantum dot.

In Table 2, the power conversion efficiency retention ratio was obtained by exposing the formed pattern to excited light of about 455 nm with a dosage of about 60 mW/cm2 for about 100 hours, measuring the power conversion efficiency in accordance with time, and calculating a power conversion efficiency retention ratio in contrast to (e.g., relative to) an initial measurement value. In addition, in Table 2, the layer state was evaluated by observing utilizing a scanning electronic microscope (SEM, HITACHI Co.) and assessing the presence or absence of exfoliation and residue.

TABLE 2

| | | | Comparative | Comparative | Comparative | Comparative | Comparative | Comparative |
|---|---|---|---|---|---|---|---|---|
| Division | Example 1 | Example 2 | Example 1 | Example 2 | Example 3 | Example 4 | Example 5 | Example 6 |
| PCE (%) | 31.3 | 35.3 | 27.4 | 31.0 | 31.0 | — | 34.7 | 34.5 |
| Retention | 97.6 | 98.1 | 88.7 | 92.4 | 96.1 | — | 74.2 | 77.3 |
| ratio (%) | | | | | | | | |
| Pattern | Normal | Normal | Normal | Torn out | Residue | Residue | Torn out | Torn out |
| state | | | | (medium) | | | (low) | (medium) |

Referring to Table 2, it can be confirmed that Example 1 and Example 2 each showed the similar level of power conversion efficiency as the Comparative Examples, while showing high power conversion efficiency retention ratios. In addition, it can be confirmed that the residue or torn out phenomenon was not generated in Example 1 and Example 2.

Regarding Comparative Example 1, the exfoliation or residue was not generated in contrast to Comparative Example 2 to Comparative Example 6, but it can be confirmed that the power conversion efficiency was markedly degraded. Comparative Example 1 corresponds to a case of not performing surface treatment separately during forming (or providing) the light control pattern and utilizing a photoresist composition having the quantum dot content (e.g., amount) of about 43 wt %. If (e.g., when) the quantum dot content (e.g., amount) is small as in Comparative Example 1, the dispersibility and the adhesiveness with a base may increase, and the formation of a stable pattern is possible, but due to the small quantum dot content (e.g., amount), optical properties may be deteriorated. In addition, in the case of Comparative Example 1 without performing surface treatment, it can be found that the affinity of the formed pattern with the base was degraded, and the power conversion efficiency retention ratio was markedly degraded in contrast to the Examples.

Regarding Comparative Example 2, it can be confirmed that the power conversion efficiency and the power conversion efficiency retention ratio increased a little compared to Comparative Example 1, but the exfoliation phenomenon of the pattern was generated. The quantum dot content (e.g., amount) increased to about 50 wt % in Comparative Example 2 compared to Comparative Example 1, and optical properties were improved due to the increased quantum dot content (e.g., amount), but dispersibility and adhesiveness with a base were degraded, and the torn out of the pattern was generated. In addition, if (e.g., when) Example 1 and Comparative Example 2 are compared, Example 1 and Comparative Example 2 included the same quantum dot content (e.g., amount) of about 50 wt %, but it can be confirmed that Example 1 including the surface modification layer showed improved adhesiveness and did not show the exfoliation phenomenon of the pattern.

If (e.g., when) Example 1 and Comparative Example 3 are compared, it can be confirmed that Comparative Example 3 showed the similar level of the power conversion efficiency and power conversion efficiency retention ratio as Example 1, but a photoresist residue was generated. In addition, if (e.g., when) Example 2 and Comparative Example 4 are compared, it can be found that the residue was generated after the developing process and the pattern was not formed in Comparative Example 4. Comparative Example 3 corresponds to a case of utilizing Comparative Compound 1 during forming (or providing) the surface modification layer compared to Example 1, and Comparative Example 4 corresponds to a case of utilizing Comparative Compound 1 during forming (or providing) the surface modification layer compared to Example 2. Comparative Compound 1 utilized in Comparative Example 3 and Comparative Example 4 corresponds to hexamethyldisilazane (HMDS) conventionally utilized during the surface treatment of a substrate. HMDS includes a hydrophobic group at its terminal and may improve affinity with the photoresist composition, but due to excessive affinity, the residue may remain in an unexposed area, and the formation of the pattern may be difficult.

If (e.g., when) Example 2 and Comparative Examples 5 and 6 are compared, it can be confirmed that Comparative Examples 5 and 6 showed similar power conversion efficiency as Example 2, but the power conversion efficiency retention ratio was degraded and the exfoliation phenomenon of the pattern was generated. Compared to Example 2, Comparative Examples 5 and 6 correspond to cases of utilizing Comparative Compounds 2 and 3, respectively, during forming (or providing) the surface modification layer. Comparative Compounds 2 and 3, respectively included in Comparative Examples 5 and 6 have a hydrophilic group at its terminal, show no adhesion improvement with the base, and the torn out phenomenon of the pattern may be induced due to the repulsion between the photoresist composition and the base. In addition, in the case of a coupling agent including a carboxyl group (—COOH) or an amine group (—NH₂) at the terminal as Comparative Compounds 2 and 3, a hydrogen ion (H+) may be provided, and the hydrogen ion (H+) provided may induce the reaction with the ligand included in the quantum dot to induce ligand separation. Accordingly, in Comparative Examples 5 and 6, it can be found that initial power conversion efficiency was high, but the stability of the quantum dot was degraded according to the time, and the power conversion efficiency retention ratio was markedly deteriorated. In comparison, Example Compound 1 included in Example 2 has a hydrophobic group at its terminal, and affinity with the photoresist composition may be improved, the ligand separation may be prevented or reduced, and high optical reliability may be shown. In addition, Example Compound 1 includes an ethylene glycol group in the center, and compatibility with the quantum dot may be improved. Accordingly, it can be confirmed that Example 2 introducing the surface modification layer including Example Compound 1 maintained the quantum dot content (e.g., amount) high, improved the adhesion of the base layer and the pattern, and showed improved pattern stability and emission efficiency properties.

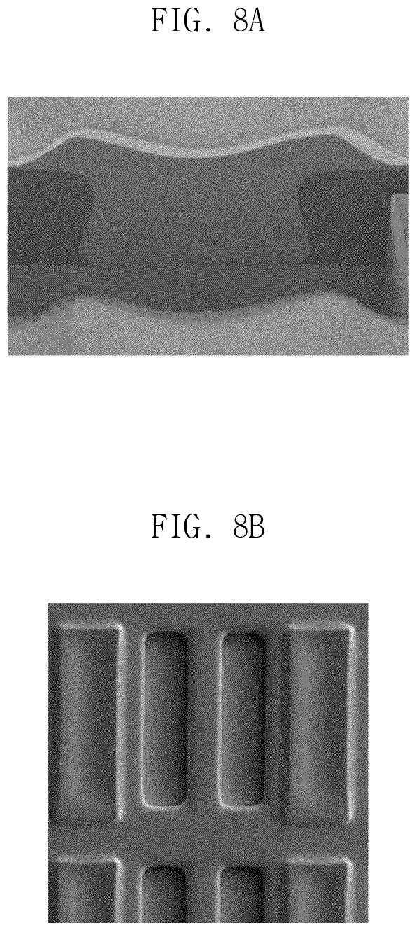

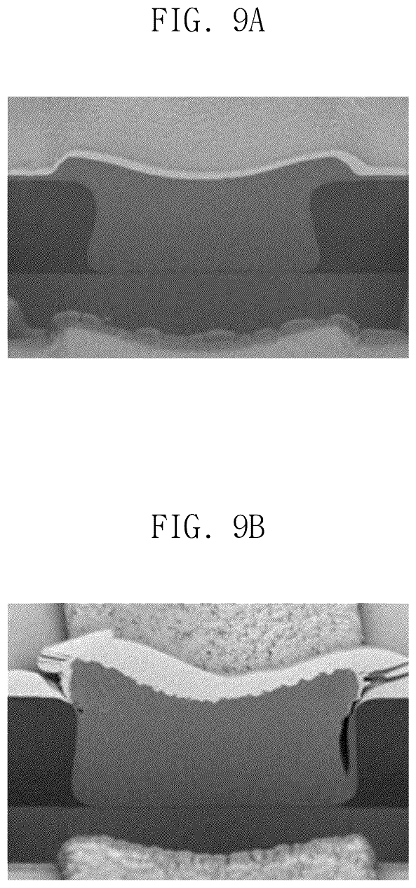

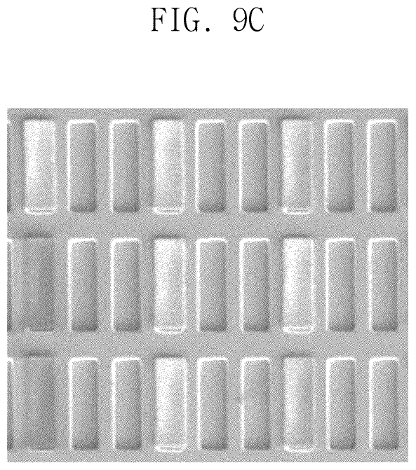

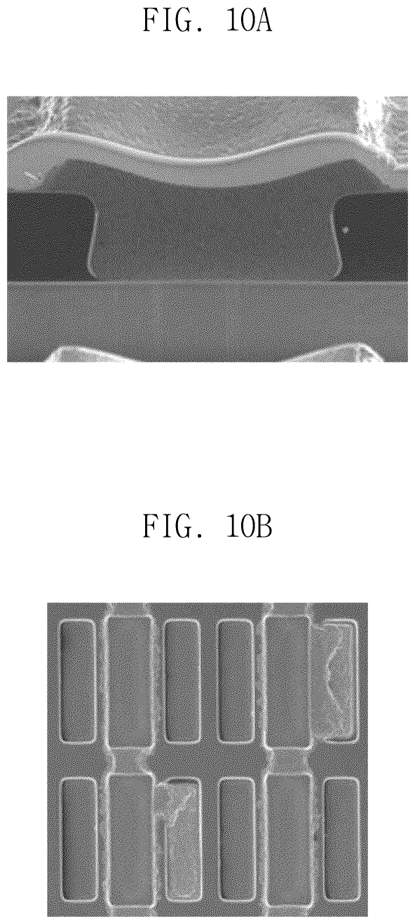

FIGS. 8A-8B, FIGS. 9A-9C, and FIGS. 10A-10B are photographic images of light control patterns of embodiments and comparative embodiments, observed by an electron microscope. FIG. 8A and FIG. 8B are each a photographic image of a light control pattern of Example 2, observed by an electron microscope. FIG. 9A is a photographic image of a light control pattern of Comparative Example 1, observed by an electron microscope. FIG. 9B and FIG. 9C are each a photographic image of a light control pattern of Comparative Example 2, observed by an electron microscope. FIG. 10A and FIG. 10B are each a photographic image of a light control pattern of Comparative Example 4, observed by an electron microscope.

Referring to FIG. 8A and FIG. 8B, it can be confirmed that in Example 2 in which a surface modification layer formed utilizing Example Compound 1 was applied, the loss or exfoliation of a pattern was not generated during a photoresist process, and tail and residue was not generated in an unexposed part.

Referring to FIG. 9A, it can be confirmed that in Comparative Example 1 in which a photoresist process was performed without surface treatment, the loss or exfoliation of a pattern was not generated as in Example 1, and tail and residue was not generated in an unexposed part. Comparative Example 1 corresponds to a case of utilizing a photoresist composition having the quantum dot content (e.g., amount) of about 43 wt %, and excellent or suitable adhesion with a base and excellent or suitable pattern properties can be shown due to the small quantum dot content (e.g., amount), but as shown in Table 2, optical properties can be markedly deteriorated due to the small quantum dot content (e.g., amount). In addition, referring to FIG. 9B and FIG. 9C, in the case of Comparative Example 2 in which the quantum dot content (e.g., amount) was increased to about 50 wt % in contrast to Comparative Example 1, it can be confirmed that the adhesion with a base was reduced due to the increased quantum dot content (e.g., amount), the torn out phenomenon of the pattern was observed, and some patterns were lost. In comparison, in the case of Example 2 shown in FIG. 8A and FIG. 8B, the surface modification layer including the coupling agent disclosed in the present disclosure was applied, and the adhesion with the base was improved and excellent or suitable pattern profile can be obtained although having the high quantum dot content (e.g., amount) of about 70 wt %.

Referring to FIG. 10A and FIG. 10B, it can be confirmed that in Comparative Example 4 in which the surface modification layer formed utilizing Comparative Compound 1 was applied, the residue was generated in an unexposed part during a photoresist process. Accordingly, it can be found that if a pattern is formed utilizing a surface treated base utilizing HMDS, different from embodiments of the present disclosure, a portion of an unexposed part may not be etched, a residue may be generated, and the application to a practical process may be difficult.

In order to accomplish a high resolution display device, a photolithography process may be utilized. However, with the increase of the resolution, there are limitations in a thickness and critical dimension (CD) in each functional layer included in the display device, and the change of optical properties due to the thickness change is very large for a light control pattern. Accordingly, technique securing optical properties by increasing the quantum dot content (e.g., amount) in a photoresist composition is desired or required. However, if (e.g., when) the quantum dot content (e.g., amount) in the photoresist composition increases, dispersion stability and photosensitivity may be reduced, and thus, defects of exfoliating a cured layer after development and/or generating a residue may occur. The exfoliation phenomenon and residue may induce the non-uniformity of the critical dimension (CD) of the photoresist pattern and may become a factor degrading the display quality of the display device.

According to the present disclosure, the light control member of one or more embodiments includes a surface modification layer including a coupling agent of the present disclosure on a base layer on which a light control pattern is formed, the quantum dot content (e.g., amount) in a photoresist composition may be maintained high during a photolithography process, and the adhesion between the base layer and a pattern may be improved. Accordingly, the durability, reliability, and display quality of the display device may be improved by minimizing or reducing the generation of exfoliation phenomenon and a residue, and at the same time, maintaining the emission efficiency of the light control pattern high.

The light control member of one or more embodiments of the present disclosure includes a surface modification layer improving the bonding force between a base layer and a light control pattern, and may show improved durability and reliability.

The display device of one or more embodiments of the present disclosure includes a light control member showing excellent or suitable durability and reliability and may show excellent or suitable display quality and reliability.

The method of manufacturing a display device of one or more embodiments of the present disclosure may provide a display device showing excellent or suitable display quality and reliability.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The light-emitting element, the display device, the electronic apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as hereinafter claimed.

Accordingly, the technical scope of the present disclosure is not intended to be limited to the content set forth in the detailed description of the present disclosure, but is intended to be defined by the appended claims and equivalents thereof.

What is claimed is:

1. A light control member, comprising:
a base layer;
a partition wall part on the base layer, multiple opening parts being defined in the partition wall part;
multiple light control patterns in the multiple opening parts; and
a surface modification layer between the base layer and the multiple light control patterns, the surface modification layer comprising a first chemical moiety represented by Formula 1:
*—(R¹)₂Si—L₁—R²—L₂—R³ Formula 1
wherein, in Formula 1, R¹ is a hydroxyl group, a substituted or unsubstituted alkoxy group of 1 to 20 carbon atoms, or a substituted or unsubstituted alkyl group of 1 to 20 carbon atoms, L₁ and L₂ are each independently a direct linkage, —O—, —S—, —NHR⁴—, —O—C(═O)—, —O—C(═S)—, —O—C(═O)R⁴—, —O—C(═S)R⁴—, —C(═O)—, —C(═S)—, —C(═O)R⁴—, —C(═S)R⁴—, —C(═O) NH—, —OC(═O) NH—, —C(═O) NHR⁴—, —OC(—O) NHR⁴—, or a substituted or unsubstituted alkylene group of 1 to 20 carbon atoms,
R² is —(O(C₂H₄))ₘ—,
R³ is a substituted or unsubstituted(meth)acrylate group, a substituted or unsubstituted alkyl group of 1 to 20 carbon atoms, or a substituted or unsubstituted aryl group of 6 to 30 ring-forming carbon atoms,
R⁴ is a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
“m” is an integer of 0 to 30, and
“*------” is a position connected with the base layer.

2. The light control member of claim 1, wherein, in Formula 1, R³ is a substituted or unsubstituted alkyl group of 1 to 10 carbon atoms.

3. The light control member of claim 1, wherein the first chemical moiety represented by Formula 1 is represented by Formula 2: 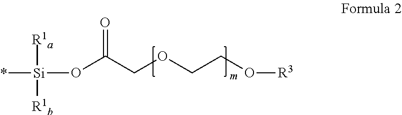
in Formula 2,
R¹ₐ and R¹_{b} being each independently a hydroxyl group, a substituted or unsubstituted alkoxy group of 1 to 20 carbon atoms, or a substituted or unsubstituted alkyl group of 1 to 20 carbon atoms, and
R³ and “m” being the same as defined in Formula 1.

4. The light control member of claim 1, wherein the surface modification layer is on a side of the base layer exposed by the multiple opening parts.

5. The light control member of claim 1, wherein the surface modification layer is in the multiple opening parts.

6. The light control member of claim 1, wherein the partition wall part comprises a first side adjacent to the base layer, a second side opposite to the first side, and a third side connecting the first side and the second side, and
at least a portion of the surface modification layer is on the third side and the second side of the partition wall part.

7. The light control member of claim 6, wherein further comprising a reflection pattern on the third side of the partition wall part, and
the surface modification layer is between the reflection pattern and the light control pattern.

8. The light control member of claim 1, wherein at least one selected from among the multiple light control patterns comprises a quantum dot.

9. The light control member of claim 8, wherein the quantum dot comprises:
a core;
a shell wrapping the core; and
a ligand bonded to a surface of the shell and comprising a hydrophilic group.

10. The light control member of claim 1, wherein the multiple light control patterns comprise:
a first light control pattern comprising a first quantum dot configured to convert source light into first light;
a second light control pattern comprising a second quantum dot configured to convert the source light into second light; and
a third light control pattern configured to transmit the source light.

11. The light control member of claim 10, wherein,
a weight of the first quantum dot is about 50 wt % to about 70 wt % on the basis of a total weight of 100 wt % of the first light control pattern, and
a weight of the second quantum dot is about 50 wt % to about 70 wt % on the basis of a total weight of 100 wt % of the second light control pattern.

12. A display device, comprising:
a light emitting element comprising a first electrode, an emission layer on the first electrode, and a second electrode on the emission layer, the light emitting element configured to emit source light; and
a light control member on the light emitting element,
wherein the light control member comprises:
a base layer on the light emitting element;
a light control layer on the light emitting element and comprising at least one light control pattern; and
a surface modification layer between the base layer and the light control pattern and comprising a first chemical moiety represented by Formula 1:
*—(R¹)₂Si—L₁—R²—L₂—R³ Formula 1
in Formula 1,
R¹ being a hydroxyl group, a substituted or unsubstituted alkoxy group of 1 to 20 carbon atoms, or a substituted or unsubstituted alkyl group of 1 to 20 carbon atoms,
L₁ and L₂ being each independently a direct linkage, —O—, —S—, —NHR⁴—, —O—C(═O)—, —O—C(═S)—, —O—C(═O)R⁴—, —O—C(═S)R⁴—, —C(═O)—, —C(═S)—, —C(═O)R⁴—, —C(═S)R⁴—, —C(═O) NH—, —OC(═O) NH—, —C(═O) NHR⁴—, —OC(═O) NHR⁴—, or a substituted or unsubstituted alkylene group of 1 to 20 carbon atoms,
R² being-(O(C₂H₄))ₘ—,
R³ being a substituted or unsubstituted(meth)acrylate group, a substituted or unsubstituted alkyl group of 1 to 20 carbon atoms, or a substituted or unsubstituted aryl group of 6 to 30 ring-forming carbon atoms,
R⁴ being a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
“m” being an integer of 0 to 30, and
“------” being a position connected with the base layer.

13. The display device of claim 12, wherein the at least one light control pattern comprise:
a first light control pattern comprising a first quantum dot configured to convert the source light into first light;
a second light control pattern comprising a second quantum dot configured to convert the source light into second light; and
a third light control pattern configured to transmit the source light.

14. The display device of claim 13, wherein,
the light control member further comprises a color filter layer on the light control layer, and
the color filter layer comprises:
a first color filter configured to transmit the first light;
a second color filter configured to transmit the second light; and
a third color filter configured to transmit the source light.

15. The display device of claim 12, wherein the base layer comprises at least one selected from among silicon oxide, silicon nitride, and silicon oxynitride.

16. The display device of claim 12, wherein,
the light control pattern comprises one side adjacent to the base layer, and the other side opposite to the one side and separated from the base layer, and
the surface modification layer contacts the one side of the light control pattern.

17. The display device of claim 12, further comprising a filling layer between the light emitting element and the light control member and covering the light emitting element.

18. A method of manufacturing a display device, the method comprising:
preparing a display panel; and
forming a light control member on the display panel,
wherein the forming of the light control member comprises:
preparing a base layer;
forming a surface modification layer comprising a first chemical moiety represented by Formula 1 on the base layer;
providing a photoresist composition comprising a quantum dot on the surface modification layer to form a preliminary light control pattern; and
exposing and developing the preliminary light control pattern to form a light control pattern:
*—(R¹)₂Si—L₁—R²—L₂—R³ Formula 1
in Formula 1,
R¹ being a hydroxyl group, a substituted or unsubstituted alkoxy group of 1 to 20 carbon atoms, or a substituted or unsubstituted alkyl group of 1 to 20 carbon atoms,
L₁ and L₂ being each independently a direct linkage, —O—, —S—, —NHR⁴—, —O—C(═O)—, —O—C(═S)—, —O—C(═O)R⁴—, —O—C(═S)R⁴—, —C(═O)—, —C(═S)—, —C(═O)R⁴—, —C(═S)R⁴—, —C(═O) NH—, —OC(═O) NH—, —C(═O) NHR⁴—, —OC(═O) NHR⁴—, or a substituted or unsubstituted alkylene group of 1 to 20 carbon atoms,
R² being —(O(C₂H₄))ₘ—,
R³ being a substituted or unsubstituted(meth)acrylate group, a substituted or unsubstituted alkyl group of 1 to 20 carbon atoms, or a substituted or unsubstituted aryl group of 6 to 30 ring-forming carbon atoms,
R⁴ being a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
“m” being an integer of 0 to 30, and
“------” being a position connected with the base layer.

19. The method of manufacturing a display device of claim 18, wherein,
the forming of the light control member further comprises forming a partition wall part on the base layer, multiple opening parts being defined in the partition wall part, prior to the forming of the surface modification layer, and
the photoresist composition is provided in the multiple opening parts.

20. The method of manufacturing a display device of claim 18, further comprising treating a surface of the base layer with ozone or ultraviolet to form a hydroxyl group on the surface of the base layer, prior to the forming of the surface modification layer.
